(19) United States
(12) Patent Application Publication
(10) Pub. No.: US 2026/0342388 A1
(43) Pub. Date: Oct. 29, 2026

(54) ENERGY THRESHOLD CONFIGURATION IN ENERGY-BASED PROBABILISTIC AMPLITUDE SHAPING

(71) Applicant: QUALCOMM Incorporated, San Diego, CA (US)

(72) Inventors: Wei LIU, Beijing (CN); Thomas Joseph RICHARDSON, South Orange, NJ (US); Liangming WU, Beijing (CN); Changlong XU, Beijing (CN); Ori SHENTAL, Marlboro, NJ (US); Hao XU, Beijing (CN)

(21) Appl. No.: 19/109,955

(22) PCT Filed: Oct. 11, 2022
(86) PCT No.: PCT/CN2022/124513

§ 371 Date: Mar. 7, 2025

(51) Int. Cl. H04B 7/06; H03M 13/09; H04B 17/318; H04L 5/00; H04W 76/20

(52) U.S. Cl. CPC H04B 7/0608; H03M 13/09; H04B 17/328; H04L 5/0044; H04W 76/20

(57) ABSTRACT

Various aspects of the present disclosure generally relate to wireless communication. In some aspects, an apparatus may determine an energy threshold based on a normalized energy threshold and an amplitude sequence length, the normalized energy threshold being based on an amplitude alphabet and a distribution parameter. The apparatus may encode a plurality of information bits into a symbol sequence with amplitude shaping, the encoding being based on the energy threshold, the amplitude alphabet, and the amplitude sequence length. The apparatus may transmit the symbol sequence encoded with amplitude shaping, the symbol sequence having a length equal to the amplitude sequence length and each symbol, of the symbol sequence, corresponding to an entry in the amplitude alphabet. Numerous other aspects are provided.

### FIELD OF THE DISCLOSURE

Aspects of the present disclosure generally relate to wireless communication and specifically, to techniques and apparatuses for energy threshold configuration in energy-based probabilistic amplitude shaping.

### BACKGROUND

Wireless communication systems are widely deployed to provide various telecommunication services such as telephony, video, data, messaging, and broadcasts. Typical wireless communication systems may employ multiple-access technologies capable of supporting communication with multiple users by sharing available system resources (for example, bandwidth or transmit power). Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, time division synchronous code division multiple access (TD-SCDMA) systems, and Long Term Evolution (LTE). LTE/LTE-Advanced is a set of enhancements to the Universal Mobile Telecommunications System (UMTS) mobile standard promulgated by the Third Generation Partnership Project (3GPP).

The above multiple access technologies have been adopted in various telecommunication standards to provide a common protocol that enables different UEs to communicate on a municipal, national, regional, or global level. New Radio (NR), which may be referred to as 5G, is a set of enhancements to the LTE mobile standard promulgated by the 3GPP. NR is designed to better support mobile broadband internet access by improving spectral efficiency, lowering costs, improving services, making use of new spectrum, and better integrating with other open standards using orthogonal frequency division multiplexing (OFDM) with a cyclic prefix (CP) (CP-OFDM) on the downlink, using CP-OFDM or single-carrier frequency division multiplexing (SC-FDM) (also known as discrete Fourier transform spread OFDM (DFT-s-OFDM)) on the uplink, as well as supporting beamforming, multiple-input multiple-output (MIMO) antenna technology, and carrier aggregation. As the demand for mobile broadband access continues to increase, further improvements in LTE, NR, and other radio access technologies remain useful.

In some wireless communications, such as when higher-order modulations are used, a transmitter device may encode information bits using fixed constellation points. For example, fixed constellation points may be used with 16-quadrature amplitude modulation (QAM), 64-QAM, or 256-QAM, among other modulation and coding schemes. The fixed constellation points may each have an equal probability of being used for encoding the information bits. For additive white Gaussian noise (AWGN) channels, a shaping gap, which may be relative to a channel capacity or “Shannon capacity”, may be present that can asymptotically approach approximately 1.53 decibels (dB) for uniformly distributed channel inputs. The shaping gap may refer to a difference between a signal to noise ratio (SNR) to achieve a given rate with a given modulation and coding scheme (MCS) and an SNR at which an optimal capacity-achieving scheme could operate, which may be the Shannon capacity or a “Shannon limit”.

Some techniques to reduce or close the shaping gap include geometric shaping and probabilistic shaping. In geometric shaping, a transmitter device may use equiprobable signaling with a non-uniform (for example, Gaussian-like) distribution of constellation points. In contrast, in probabilistic shaping, the transmitter device may use equidistant constellation points with non-uniform (for example, Gaussian-like) signal distribution. To perform probabilistic shaping, the transmitter device may determine an energy threshold E such that there is a non-uniform distribution over a set of amplitude symbols induced by an energy-based shaping scheme. If the non-uniform distribution is relatively different than an optimal Maxwell-Boltzmann (MB) distribution, the shaping gap may be excessively large, which may result in poor communication performance.

### SUMMARY

Some aspects described herein relate to a method of wireless communication performed by an apparatus of a transmitter device. The method may include determining an energy threshold based on a normalized energy threshold and an amplitude sequence length, the normalized energy threshold being based on an amplitude alphabet and a distribution parameter. The method may include encoding a plurality of information bits into a symbol sequence with amplitude shaping, the encoding being based on the energy threshold, the amplitude alphabet, and the amplitude sequence length. The method may include transmitting the symbol sequence encoded with amplitude shaping, the symbol sequence having a length equal to the amplitude sequence length and each symbol, of the symbol sequence, corresponding to an entry in the amplitude alphabet.

Some aspects described herein relate to a transmitter device for wireless communication. The transmitter device may include at least one processor and at least one memory, communicatively coupled with the at least one processor, that stores processor-readable code. The processor-readable code, when executed by the at least one processor, may be configured to cause the transmitter device to determine an energy threshold based on a normalized energy threshold and an amplitude sequence length, the normalized energy threshold being based on an amplitude alphabet and a distribution parameter. The processor-readable code, when executed by the at least one processor, may be configured to cause the transmitter device to encode a plurality of information bits into a symbol sequence with amplitude shaping, the encoding being based on the energy threshold, the amplitude alphabet, and the amplitude sequence length. The processor-readable code, when executed by the at least one processor, may be configured to cause the transmitter device to transmit the symbol sequence encoded with amplitude shaping, the symbol sequence having a length equal to the amplitude sequence length and each symbol, of the symbol sequence, corresponding to an entry in the amplitude alphabet.

Some aspects described herein relate to a non-transitory computer-readable medium that stores a set of instructions for wireless communication by a transmitter device. The set of instructions, when executed by one or more processors of the transmitter device, may cause the transmitter device to determine an energy threshold based on a normalized energy threshold and an amplitude sequence length, the normalized energy threshold being based on an amplitude alphabet and a distribution parameter. The set of instructions, when executed by one or more processors of the transmitter device, may cause the transmitter device to encode a plurality of information bits into a symbol sequence with amplitude shaping, the encoding being based on the energy threshold, the amplitude alphabet, and the amplitude sequence length. The set of instructions, when executed by one or more processors of the transmitter device, may cause the transmitter device to transmit the symbol sequence encoded with amplitude shaping, the symbol sequence having a length equal to the amplitude sequence length and each symbol, of the symbol sequence, corresponding to an entry in the amplitude alphabet.

Some aspects described herein relate to an apparatus for wireless communication. The apparatus may include means for determining an energy threshold based on a normalized energy threshold and an amplitude sequence length, the normalized energy threshold being based on an amplitude alphabet and a distribution parameter. The apparatus may include means for encoding a plurality of information bits into a symbol sequence with amplitude shaping, the encoding being based on the energy threshold, the amplitude alphabet, and the amplitude sequence length. The apparatus may include means for transmitting the symbol sequence encoded with amplitude shaping, the symbol sequence having a length equal to the amplitude sequence length and each symbol, of the symbol sequence, corresponding to an entry in the amplitude alphabet.

Aspects generally include a method, apparatus, system, computer program product, non-transitory computer-readable medium, user equipment, base station, network node, network entity, wireless communication device, or processing system as substantially described with reference to and as illustrated by the drawings and specification.

The foregoing has outlined rather broadly the features and technical advantages of examples in accordance with the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only some typical aspects of this disclosure and are therefore not to be considered limiting of its scope, for the description may admit to other equally effective aspects. The same reference numbers in different drawings may identify the same or similar elements.

FIG. 1 is a diagram illustrating an example of a wireless network in accordance with the present disclosure.

FIG. 2 is a diagram illustrating an example network node in communication with a UE in a wireless network in accordance with the present disclosure.

FIG. 3 is a diagram illustrating an example disaggregated base station architecture in accordance with the present disclosure.

FIG. 4 is a diagram illustrating an example of a transmit (Tx) chain and a receive (Rx) chain of a UE in accordance with the present disclosure.

FIG. 5 is a diagram illustrating an example transmit chain for probabilistic amplitude shaping in accordance with the present disclosure.

FIG. 6 is a diagram illustrating an example transmit chain for probabilistic amplitude shaping in accordance with the present disclosure.

FIG. 7 is a diagram illustrating an example of shaping gain over an additive white Gaussian noise (AWGN) channel in accordance with the present disclosure.

FIGS. 8A-8F are diagrams illustrating examples associated with energy threshold configuration in energy-based probabilistic amplitude shaping in accordance with the present disclosure.

FIG. 9 is a flowchart illustrating an example process performed, for example, by a transmitter device that supports energy threshold configuration in energy-based probabilistic amplitude shaping in accordance with the present disclosure.

FIG. 10 is a diagram of an example apparatus for wireless communication that supports energy threshold configuration in energy-based probabilistic amplitude shaping in accordance with the present disclosure.

### DETAILED DESCRIPTION

Various aspects of the disclosure are described more fully hereinafter with reference to the accompanying drawings. This disclosure may, however, be embodied in many different forms and are not to be construed as limited to any specific structure or function presented throughout this disclosure. Rather, these aspects are provided so that this disclosure will be thorough and complete, and will fully convey the scope of the disclosure to those skilled in the art. One skilled in the art may appreciate that the scope of the disclosure is intended to cover any aspect of the disclosure disclosed herein, whether implemented independently of or combined with any other aspect of the disclosure. For example, an apparatus may be implemented or a method may be practiced using any quantity of the aspects set forth herein. In addition, the scope of the disclosure is intended to cover such an apparatus or method which is practiced using other structure, functionality, or structure and functionality in addition to or other than the various aspects of the disclosure set forth herein. Any aspect of the disclosure disclosed herein may be embodied by one or more elements of a claim.

Several aspects of telecommunication systems will now be presented with reference to various apparatuses and techniques. These apparatuses and techniques will be described in the following detailed description and illustrated in the accompanying drawings by various blocks, modules, components, circuits, steps, processes, or algorithms (collectively referred to as “elements”). These elements may be implemented using hardware, software, or a combination of hardware and software. Whether such elements are implemented as hardware or software depends upon the particular application and design constraints imposed on the overall system.

Various aspects relate generally to determining an energy threshold for energy-based probabilistic amplitude shaping. Some aspects more specifically relate to determining an energy threshold based on an amplitude alphabet, a distribution parameter (such as a Maxwell-Boltzmann (MB) parameter), and an amplitude sequence length. In some aspects, a transmitter device may use a polynomial representation or a table-based representation of a normalized energy threshold to determine the energy threshold. Based on determining the energy threshold, the transmitter device can apply energy-based encoding for amplitude shaping of a plurality of information bits to generate a set of symbols for transmission.

Particular aspects of the subject matter described in this disclosure can be implemented to realize one or more of the following potential advantages. In some examples, the described techniques can be used to minimize a shaping gap. By determining an energy threshold, such that a non-uniform distribution over a set of amplitude symbols induced by an energy-shaping scheme for amplitude shaping of a plurality of input bits is as close to an optimal probability distribution (such as an MB distribution) as possible, the transmitter device reduces a size of the shaping gap relative to other techniques for probabilistic amplitude shaping. In some example, the transmitter device may improve communication performance. For example, based on minimizing or reducing a shaping gap, the transmitter device increases a likelihood that a set of symbols are successfully transmitted to and decoded by a receiver device. This may reduce an amount of network traffic by reducing a quantity of retransmissions that are triggered for dropped or unsuccessfully decoded symbols.

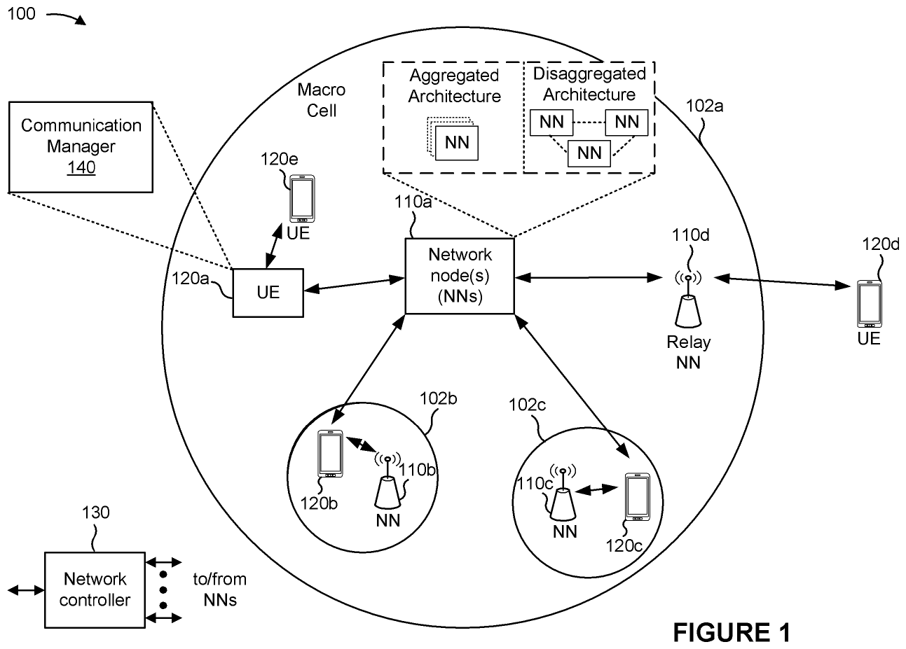

FIG. 1 is a diagram illustrating an example of a wireless network in accordance with the present disclosure. The wireless network 100 may be or may include elements of a 5G (for example, NR) network or a 4G (for example, Long Term Evolution (LTE)) network, among other examples. The wireless network 100 may include one or more network nodes 110 (shown as a network node (NN) 110a, a network node 110b, a network node 110c, and a network node 110d), a user equipment (UE) 120 or multiple UEs 120 (shown as a UE 120a, a UE 120b, a UE 120c, a UE 120d, and a UE 120e), or other network entities. A network node 110 is an entity that communicates with UEs 120. As shown, a network node 110 may include one or more network nodes. For example, a network node 110 may be an aggregated network node, meaning that the aggregated network node is configured to utilize a radio protocol stack that is physically or logically integrated within a single RAN node (for example, within a single device or unit). As another example, a network node 110 may be a disaggregated network node (sometimes referred to as a disaggregated base station), meaning that the network node 110 is configured to utilize a protocol stack that is physically or logically distributed among two or more nodes (such as one or more central units (CUs), one or more distributed units (DUs), or one or more radio units (RUs)).

In some examples, a network node 110 is or includes a network node that communicates with UEs 120 via a radio access link, such as an RU. In some examples, a network node 110 is or includes a network node that communicates with other network nodes 110 via a fronthaul link or a midhaul link, such as a DU. In some examples, a network node 110 is or includes a network node that communicates with other network nodes 110 via a midhaul link or a core network via a backhaul link, such as a CU. In some examples, a network node 110 (such as an aggregated network node 110 or a disaggregated network node 110) may include multiple network nodes, such as one or more RUs, one or more CUs, or one or more DUs. A network node 110 may include, for example, an NR network node, an LTE network node, a Node B, an eNB (for example, in 4G), a gNB (for example, in 5G), an access point, or a transmission reception point (TRP), a DU, an RU, a CU, a mobility element of a network, a core network node, a network element, a network equipment, or a RAN node. In some examples, the network nodes 110 may be interconnected to one another or to one or more other network nodes 110 in the wireless network 100 through various types of fronthaul, midhaul, or backhaul interfaces, such as a direct physical connection, an air interface, or a virtual network, using any suitable transport network.

Each network node 110 may provide communication coverage for a particular geographic area. In the Third Generation Partnership Project (3GPP), the term “cell” can refer to a coverage area of a network node 110 or a network node subsystem serving this coverage area, depending on the context in which the term is used.

A network node 110 may provide communication coverage for a macro cell, a pico cell, a femto cell, or another type of cell. A macro cell may cover a relatively large geographic area (for example, several kilometers in radius) and may allow unrestricted access by UEs 120 with service subscriptions. A pico cell may cover a relatively small geographic area and may allow unrestricted access by UEs 120 with service subscription. A femto cell may cover a relatively small geographic area (for example, a home) and may allow restricted access by UEs 120 having association with the femto cell (for example, UEs 120 in a closed subscriber group (CSG)). A network node 110 for a macro cell may be referred to as a macro network node. A network node 110 for a pico cell may be referred to as a pico network node. A network node 110 for a femto cell may be referred to as a femto network node or an in-home network node.

The wireless network 100 may be a heterogeneous network that includes network nodes 110 of different types, such as macro network nodes, pico network nodes, femto network nodes, or relay network nodes. These different types of network nodes 110 may have different transmit power levels, different coverage areas, or different impacts on interference in the wireless network 100. For example, macro network nodes may have a high transmit power level (for example, 5 to 40 watts) whereas pico network nodes, femto network nodes, and relay network nodes may have lower transmit power levels (for example, 0.1 to 2 watts). In the example shown in FIG. 1, the network node 110a may be a macro network node for a macro cell 102a, the network node 110b may be a pico network node for a pico cell 102b, and the network node 110c may be a femto network node for a femto cell 102c. A network node may support one or multiple (for example, three) cells. In some examples, a cell may not necessarily be stationary, and the geographic area of the cell may move in accordance with the location of a network node 110 that is mobile (for example, a mobile network node).

In some aspects, the term “base station” or “network node” may refer to an aggregated base station, a disaggregated base station, an integrated access and backhaul (IAB) node, a relay node, or one or more components thereof. For example, in some aspects, “base station” or “network node” may refer to a CU, a DU, an RU, a Near-Real Time (Near-RT) RAN Intelligent Controller (RIC), or a Non-Real Time (Non-RT) RIC. In some aspects, the term “base station” or “network node” may refer to one device configured to perform one or more functions, such as those described herein in connection with the network node 110. In some aspects, the term “base station” or “network node” may refer to a plurality of devices configured to perform the one or more functions. For example, in some distributed systems, each of a quantity of different devices (which may be located in the same geographic location or in different geographic locations) may be configured to perform at least a portion of a function, or to duplicate performance of at least a portion of the function, and the term “base station” or “network node” may refer to any one or more of those different devices. In some aspects, the term “base station” or “network node” may refer to one or more virtual base stations or one or more virtual base station functions. For example, in some aspects, two or more base station functions may be instantiated on a single device. In some aspects, the term “base station” or “network node” may refer to one of the base station functions and not another. In this way, a single device may include more than one base station.

A network controller 130 may couple to or communicate with a set of network nodes 110 and may provide coordination and control for these network nodes 110. The network controller 130 may communicate with the network nodes 110 via a backhaul communication link. The network nodes 110 may communicate with one another directly or indirectly via a wireless or wireline backhaul communication link. In some aspects, the network controller 130 may be a CU or a core network device, or the network controller 130 may include a CU or a core network device.

In some examples, a cell may not necessarily be stationary, and the geographic area of the cell may move in accordance with the location of a network node 110 that is mobile (for example, a mobile network node). In some examples, the network nodes 110 may be interconnected to one another or to one or more other network nodes 110 or network nodes (not shown) in the wireless network 100 through various types of backhaul interfaces, such as a direct physical connection or a virtual network, using any suitable transport network.

The wireless network 100 may include one or more relay stations. A relay station is an entity that can receive a transmission of data from an upstream station (for example, a network node 110 or a UE 120) and send a transmission of the data to a downstream station (for example, a UE 120 or a network node 110). A relay station may be a UE 120 that can relay transmissions for other UEs 120. In the example shown in FIG. 1, the network node 110d (for example, a relay network node) may communicate with the network node 110a (for example, a macro network node) and the UE 120d in order to facilitate communication between the network node 110a and the UE 120d. A network node 110 that relays communications may be referred to as a relay station, a relay network node, or a relay.

The UEs 120 may be dispersed throughout the wireless network 100, and each UE 120 may be stationary or mobile. A UE 120 may include, for example, an access terminal, a terminal, a mobile station, or a subscriber unit. A UE 120 may be a cellular phone (for example, a smart phone), a personal digital assistant (PDA), a wireless modem, a wireless communication device, a handheld device, a laptop computer, a cordless phone, a wireless local loop (WLL) station, a tablet, a camera, a gaming device, a netbook, a smartbook, an ultrabook, a medical device, a biometric device, a wearable device (for example, a smart watch, smart clothing, smart glasses, a smart wristband, smart jewelry (for example, a smart ring or a smart bracelet)), an entertainment device (for example, a music device, a video device, or a satellite radio), a vehicular component or sensor, a smart meter/sensor, industrial manufacturing equipment, a global positioning system device, a UE function of a network node, or any other suitable device that is configured to communicate via a wireless medium.

Some UEs 120 may be considered machine-type communication (MTC) or evolved or enhanced machine-type communication (eMTC) UEs. An MTC UE or an eMTC UE may include, for example, a robot, a drone, a remote device, a sensor, a meter, a monitor, or a location tag, that may communicate with a network node, another device (for example, a remote device), or some other entity. Some UEs 120 may be considered Internet-of-Things (IoT) devices, or may be implemented as NB-IoT (narrowband IoT) devices. Some UEs 120 may be considered a Customer Premises Equipment. A UE 120 may be included inside a housing that houses components of the UE 120, such as processor components or memory components. In some examples, the processor components and the memory components may be coupled together. For example, the processor components (for example, one or more processors) and the memory components (for example, a memory) may be operatively coupled, communicatively coupled, electronically coupled, or electrically coupled.

In general, any quantity of wireless networks 100 may be deployed in a given geographic area. Each wireless network 100 may support a particular RAT and may operate on one or more frequencies. A RAT may be referred to as a radio technology or an air interface. A frequency may be referred to as a carrier or a frequency channel. Each frequency may support a single RAT in a given geographic area in order to avoid interference between wireless networks of different RATs. In some cases, NR or 5G RAT networks may be deployed.

In some examples, two or more UEs 120 (for example, shown as UE 120a and UE 120e) may communicate directly using one or more sidelink channels (for example, without using a network node 110 as an intermediary to communicate with one another). For example, the UEs 120 may communicate using peer-to-peer (P2P) communications, device-to-device (D2D) communications, a vehicle-to-everything (V2X) protocol (for example, which may include a vehicle-to-vehicle (V2V) protocol, a vehicle-to-infrastructure (V2I) protocol, or a vehicle-to-pedestrian (V2P) protocol), or a mesh network. In such examples, a UE 120 may perform scheduling operations, resource selection operations, or other operations described elsewhere herein as being performed by the network node 110.

Devices of the wireless network 100 may communicate using the electromagnetic spectrum, which may be subdivided by frequency or wavelength into various classes, bands, or channels. For example, devices of the wireless network 100 may communicate using one or more operating bands. In 5G NR, two initial operating bands have been identified as frequency range designations FR1 (410 MHz-7.125 GHz) and FR2 (24.25 GHz-52.6 GHz). Although a portion of FR1 is greater than 6 GHz, FR1 is often referred to (interchangeably) as a “Sub-6 GHz” band in various documents and articles. A similar nomenclature issue sometimes occurs in connection with FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHz-24.25 GHz). Frequency bands falling within FR3 may inherit FR1 characteristics or FR2 characteristics, and thus may effectively extend features of FR1 or FR2 into mid-band frequencies. In addition, higher frequency bands are currently being explored to extend 5G NR operation beyond 52.6 GHz. For example, three higher operating bands have been identified as frequency range designations FR4a or FR4-1 (52.6 GHz-71 GHz), FR4 (52.6 GHz-114.25 GHz), and FR5 (114.25 GHz-300 GHz). Each of these higher frequency bands falls within the EHF band.

With the above examples in mind, unless specifically stated otherwise, the term “sub-6 GHz,” if used herein, may broadly represent frequencies that may be less than 6 GHz, may be within FR1, or may include mid-band frequencies. Further, unless specifically stated otherwise, the term “millimeter wave,” if used herein, may broadly represent frequencies that may include mid-band frequencies, may be within FR2, FR4, FR4-a or FR4-1, or FR5, or may be within the EHF band. It is contemplated that the frequencies included in these operating bands (for example, FR1, FR2, FR3, FR4, FR4-a, FR4-1, or FR5) may be modified, and techniques described herein are applicable to those modified frequency ranges.

In some aspects, a transmitter device, such as the UE 120, may include a communication manager 140. As described in more detail elsewhere herein, the communication manager 140 may determine an energy threshold based on a normalized energy threshold and an amplitude sequence length, the normalized energy threshold being based on an amplitude alphabet and a distribution parameter; encode a plurality of information bits into a symbol sequence with amplitude shaping, the encoding being based on the energy threshold, the amplitude alphabet, and the amplitude sequence length; and transmit the symbol sequence encoded with amplitude shaping, the symbol sequence having a length equal to the amplitude sequence length and each symbol, of the symbol sequence, corresponding to an entry in the amplitude alphabet. Additionally or alternatively, the communication manager 140 may perform one or more other operations described herein.

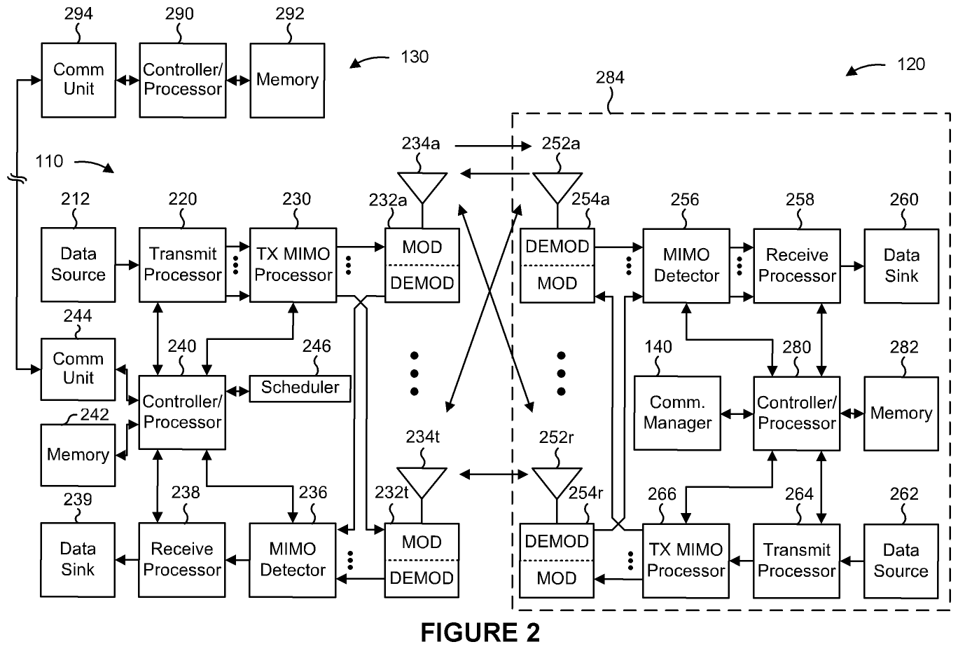

FIG. 2 is a diagram illustrating an example network node in communication with a UE in a wireless network in accordance with the present disclosure. The network node may correspond to the network node 110 of FIG. 1. Similarly, the UE may correspond to the ULE 120 of FIG. 1. The network node 110 may be equipped with a set of antennas 234a through 234t, such as T antennas (T≥>1). The UE 120 may be equipped with a set of antennas 252a through 252r, such as R antennas (R≥1). The network node 110 of depicted in FIG. 2 includes one or more radio frequency components, such as antennas 234 and a modem 254. In some examples, a network node 110 may include an interface, a communication component, or another component that facilitates communication with the UE 120 or another network node. Some network nodes 110 may not include radio frequency components that facilitate direct communication with the UE 120, such as one or more CUs, or one or more DUs.

At the network node 110, a transmit processor 220 may receive data, from a data source 212, intended for the UE 120 (or a set of UEs 120). The transmit processor 220 may select one or more modulation and coding schemes (MCSs) for the UE 120 based at least in part on one or more channel quality indicators (CQIs) received from that UE 120. The network node 110 may process (for example, encode and modulate) the data for the UE 120 based at least in part on the MCS(s) selected for the UE 120 and may provide data symbols for the UE 120. The transmit processor 220 may process system information (for example, for semi-static resource partitioning information (SRPI)) and control information (for example, CQI requests, grants, or upper layer signaling) and provide overhead symbols and control symbols. The transmit processor 220 may generate reference symbols for reference signals (for example, a cell-specific reference signal (CRS) or a demodulation reference signal (DMRS)) and synchronization signals (for example, a primary synchronization signal (PSS) or a secondary synchronization signal (SSS)). A transmit (TX) multiple-input multiple-output (MIMO) processor 230 may perform spatial processing (for example, precoding) on the data symbols, the control symbols, the overhead symbols, or the reference symbols, if applicable, and may provide a set of output symbol streams (for example, T output symbol streams) to a corresponding set of modems 232 (for example, T modems), shown as modems 232a through 232t. For example, each output symbol stream may be provided to a modulator component (shown as MOD) of a modem 232. Each modem 232 may use a respective modulator component to process a respective output symbol stream (for example, for OFDM) to obtain an output sample stream. Each modem 232 may further use a respective modulator component to process (for example, convert to analog, amplify, filter, or upconvert) the output sample stream to obtain a downlink signal. The modems 232a through 232t may transmit a set of downlink signals (for example, T downlink signals) via a corresponding set of antennas 234 (for example, T antennas), shown as antennas 234a through 234t.

At the UE 120, a set of antennas 252 (shown as antennas 252a through 252r) may receive the downlink signals from the network node 110 or other network nodes 110 and may provide a set of received signals (for example, R received signals) to a set of modems 254 (for example, R modems), shown as modems 254a through 254r. For example, each received signal may be provided to a demodulator component (shown as DEMOD) of a modem 254. Each modem 254 may use a respective demodulator component to condition (for example, filter, amplify, downconvert, or digitize) a received signal to obtain input samples. Each modem 254 may use a demodulator component to further process the input samples (for example, for OFDM) to obtain received symbols. A MIMO detector 256 may obtain received symbols from the modems 254, may perform MIMO detection on the received symbols if applicable, and may provide detected symbols. A receive processor 258 may process (for example, demodulate and decode) the detected symbols, may provide decoded data for the UE 120 to a data sink 260, and may provide decoded control information and system information to a controller/processor 280. The term “controller/processor” may refer to one or more controllers or one or more processors. A channel processor may determine a reference signal received power (RSRP) parameter, a received signal strength indicator (RSSI) parameter, a reference signal received quality (RSRQ) parameter, or a CQI parameter, among other examples. In some examples, one or more components of the UE 120 may be included in a housing 284.

The network controller 130 may include a communication unit 294, a controller/processor 290, and a memory 292. The network controller 130 may include, for example, one or more devices in a core network. The network controller 130 may communicate with the network node 110 via the communication unit 294.

One or more antennas (for example, antennas 234a through 234t or antennas 252a through 252r) may include, or may be included within, one or more antenna panels, one or more antenna groups, one or more sets of antenna elements, or one or more antenna arrays, among other examples. An antenna panel, an antenna group, a set of antenna elements, or an antenna array may include one or more antenna elements (within a single housing or multiple housings), a set of coplanar antenna elements, a set of non-coplanar antenna elements, or one or more antenna elements coupled to one or more transmission or reception components, such as one or more components of FIG. 2.

On the uplink, at the UE 120, a transmit processor 264 may receive and process data from a data source 262 and control information (for example, for reports that include RSRP, RSSI, RSRQ, or CQI) from the controller/processor 280. The transmit processor 264 may generate reference symbols for one or more reference signals. The symbols from the transmit processor 264 may be precoded by a TX MIMO processor 266 if applicable, further processed by the modems 254 (for example, for DFT-s-OFDM or CP-OFDM), and transmitted to the network node 110. In some examples, the modem 254 of the UE 120 may include a modulator and a demodulator. In some examples, the UE 120 includes a transceiver. The transceiver may include any combination of the antenna(s) 252, the modem(s) 254, the MIMO detector 256, the receive processor 258, the transmit processor 264, or the TX MIMO processor 266. The transceiver may be used by a processor (for example, the controller/processor 280) and the memory 282 to perform aspects of any of the methods described herein.

At the network node 110, the uplink signals from UE 120 or other UEs may be received by the antennas 234, processed by the modem 232 (for example, a demodulator component, shown as DEMOD, of the modem 232), detected by a MIMO detector 236 if applicable, and further processed by a receive processor 238 to obtain decoded data and control information sent by the UE 120. The receive processor 238 may provide the decoded data to a data sink 239 and provide the decoded control information to the controller/processor 240. The network node 110 may include a communication unit 244 and may communicate with the network controller 130 via the communication unit 244. The network node 110 may include a scheduler 246 to schedule one or more UEs 120 for downlink or uplink communications. In some examples, the modem 232 of the network node 110 may include a modulator and a demodulator. In some examples, the network node 110 includes a transceiver. The transceiver may include any combination of the antenna(s) 234, the modem(s) 232, the MIMO detector 236, the receive processor 238, the transmit processor 220, or the TX MIMO processor 230. The transceiver may be used by a processor (for example, the controller/processor 240) and the memory 242 to perform aspects of any of the methods described herein.

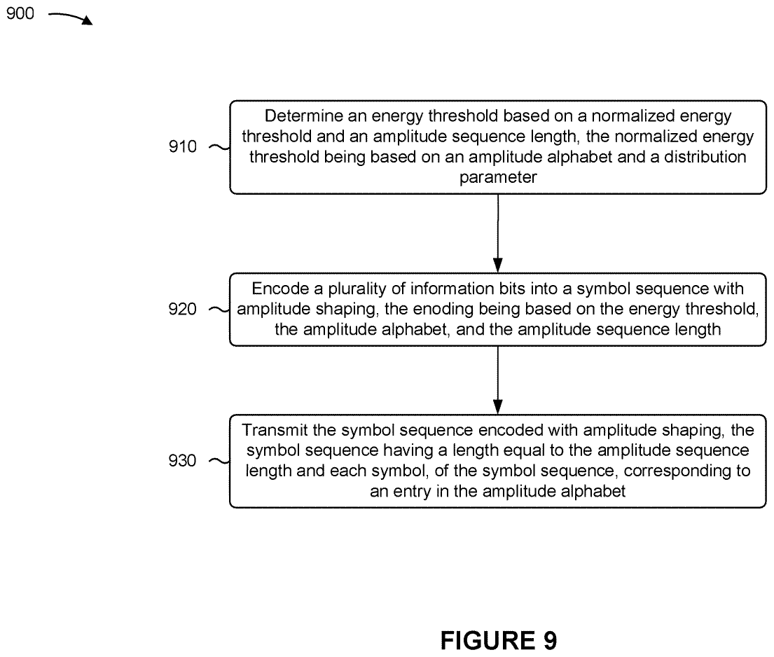

The controller/processor 240 of the network node 110, the controller/processor 280 of the UE 120, or any other component(s) of FIG. 2 may perform one or more techniques associated with energy threshold configuration in energy-based probabilistic amplitude shaping, as described in more detail elsewhere herein. For example, the controller/processor 240 of the network node 110, the controller/processor 280 of the UE 120, or any other component(s) of FIG. 2 may perform or direct operations of, for example, process 900 of FIG. 9 or other processes as described herein. The memory 242 and the memory 282 may store data and program codes for the network node 110 and the UE 120, respectively. In some examples, the memory 242 or the memory 282 may include a non-transitory computer-readable medium storing one or more instructions (for example, code or program code) for wireless communication. For example, the one or more instructions, when executed (for example, directly, or after compiling, converting, or interpreting) by one or more processors of the network node 110 or the UE 120, may cause the one or more processors, the UE 120, or the network node 110 to perform or direct operations of, for example, process 900 of FIG. 9 or other processes as described herein. In some examples, executing instructions may include running the instructions, converting the instructions, compiling the instructions, or interpreting the instructions, among other examples.

In some aspects, a transmitter device, such as the UE 120, includes means for determining an energy threshold based on a normalized energy threshold and an amplitude sequence length, the normalized energy threshold being based on an amplitude alphabet and a distribution parameter; means for encoding a plurality of information bits into a symbol sequence with amplitude shaping, the encoding being based on the energy threshold, the amplitude alphabet, and the amplitude sequence length; or means for transmitting the symbol sequence encoded with amplitude shaping, the symbol sequence having a length equal to the amplitude sequence length and each symbol, of the symbol sequence, corresponding to an entry in the amplitude alphabet. In some aspects, the means for the transmitter device to perform operations described herein may include, for example, one or more of communication manager 140, antenna 252, modem 254, MIMO detector 256, receive processor 258, transmit processor 264, TX MIMO processor 266, controller/processor 280, or memory 282.

Deployment of communication systems, such as 5G NR systems, may be arranged in multiple manners with various components or constituent parts. In a 5G NR system, or network, a network node, a network entity, a mobility element of a network, a RAN node, a core network node, a network element, a base station, or a network equipment may be implemented in an aggregated or disaggregated architecture. For example, a base station (such as a Node B (NB), an evolved NB (eNB), an NR BS, a 5G NB, an access point (AP), a TRP, or a cell, among other examples), or one or more units (or one or more components) performing base station functionality, may be implemented as an aggregated base station (also known as a standalone base station or a monolithic base station) or a disaggregated base station. “Network entity” or “network node” may refer to a disaggregated base station, or to one or more units of a disaggregated base station (such as one or more CUs, one or more DUs, or one or more RUs).

An aggregated base station (for example, an aggregated network node) may be configured to utilize a radio protocol stack that is physically or logically integrated within a single RAN node (for example, within a single device or unit). A disaggregated base station (for example, a disaggregated network node) may be configured to utilize a protocol stack that is physically or logically distributed among two or more units (such as one or more CUs, one or more DUs, or one or more RUs). In some examples, a CU may be implemented within a network node, and one or more DUs may be co-located with the CU, or alternatively, may be geographically or virtually distributed throughout one or multiple other network nodes. The DUs may be implemented to communicate with one or more RUs. Each of the CU, DU and RU also can be implemented as virtual units, such as a virtual central unit (VCU), a virtual distributed unit (VDU), or a virtual radio unit (VRU), among other examples.

Base station-type operation or network design may consider aggregation characteristics of base station functionality. For example, disaggregated base stations may be utilized in an IAB network, an open radio access network (O-RAN (such as the network configuration sponsored by the O-RAN Alliance)), or a virtualized radio access network (vRAN, also known as a cloud radio access network (C-RAN)) to facilitate scaling of communication systems by separating base station functionality into one or more units that can be individually deployed. A disaggregated base station may include functionality implemented across two or more units at various physical locations, as well as functionality implemented for at least one unit virtually, which can enable flexibility in network design. The various units of the disaggregated base station can be configured for wired or wireless communication with at least one other unit of the disaggregated base station.

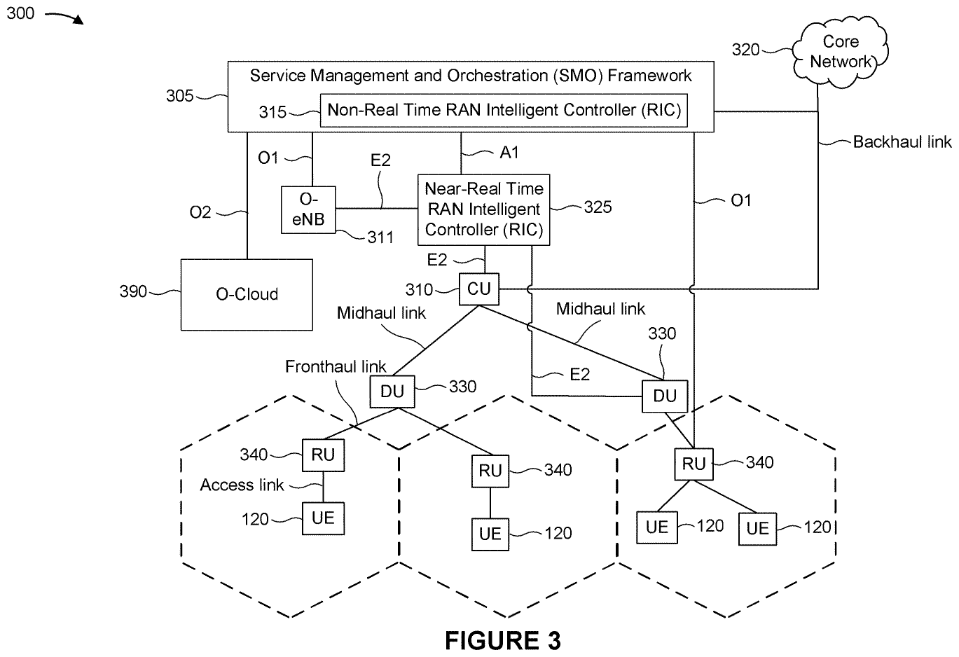

FIG. 3 is a diagram illustrating an example disaggregated base station architecture 300 in accordance with the present disclosure. The disaggregated base station architecture 300 may include a CU 310 that can communicate directly with a core network 320 via a backhaul link, or indirectly with the core network 320 through one or more disaggregated control units (such as a Near-RT RIC 325 via an E2 link, or a Non-RT RIC 315 associated with a Service Management and Orchestration (SMO) Framework 305, or both). A CU 310 may communicate with one or more DUs 330 via respective midhaul links, such as through F1 interfaces. Each of the DUs 330 may communicate with one or more RUs 340 via respective fronthaul links. Each of the RUs 340 may communicate with one or more UEs 120 via respective radio frequency (RF) access links. In some implementations, a UE 120 may be simultaneously served by multiple RUs 340.

Each of the units, including the CUs 310, the DUs 330, the RUs 340, as well as the Near-RT RICs 325, the Non-RT RICs 315, and the SMO Framework 305, may include one or more interfaces or be coupled with one or more interfaces configured to receive or transmit signals, data, or information (collectively, signals) via a wired or wireless transmission medium. Each of the units, or an associated processor or controller providing instructions to one or multiple communication interfaces of the respective unit, can be configured to communicate with one or more of the other units via the transmission medium. In some examples, each of the units can include a wired interface, configured to receive or transmit signals over a wired transmission medium to one or more of the other units, and a wireless interface, which may include a receiver, a transmitter or transceiver (such as a RF transceiver), configured to receive or transmit signals, or both, over a wireless transmission medium to one or more of the other units.

In some aspects, the CU 310 may host one or more higher layer control functions. Such control functions can include radio resource control (RRC) functions, packet data convergence protocol (PDCP) functions, or service data adaptation protocol (SDAP) functions, among other examples. Each control function can be implemented with an interface configured to communicate signals with other control functions hosted by the CU 310. The CU 310 may be configured to handle user plane functionality (for example, Central Unit-User Plane (CU-UP) functionality), or control plane functionality (for example, Central Unit-Control Plane (CU-CP) functionality). In some implementations, the CU 310 can be logically split into one or more CU-UP units and one or more CU-CP units. A CU-UP unit can communicate bidirectionally with a CU-CP unit via an interface, such as the E1 interface when implemented in an O-RAN configuration. The CU 310 can be implemented to communicate with a DU 330, as necessary, for network control and signaling.

Each DU 330 may correspond to a logical unit that includes one or more base station functions to control the operation of one or more RUs 340. In some aspects, the DU 330 may host one or more of a radio link control (RLC) layer, a MAC layer, and one or more high physical (PHY) layers depending, at least in part, on a functional split, such as a functional split defined by the 3GPP. In some aspects, the one or more high PHY layers may be implemented by one or more modules for forward error correction (FEC) encoding and decoding, scrambling, and modulation and demodulation, among other examples. In some aspects, the DU 330 may further host one or more low PHY layers, such as implemented by one or more modules for a fast Fourier transform (FFT), an inverse FFT (iFFT), digital beamforming, or physical random access channel (PRACH) extraction and filtering, among other examples. Each layer (which also may be referred to as a module) can be implemented with an interface configured to communicate signals with other layers (and modules) hosted by the DU 330, or with the control functions hosted by the CU 310.

Each RU 340 may implement lower-layer functionality. In some deployments, an RU 340, controlled by a DU 330, may correspond to a logical node that hosts RF processing functions or low-PHY layer functions, such as performing an FFT, performing an iFFT, digital beamforming, or PRACH extraction and filtering, among other examples, based on a functional split (for example, a functional split defined by the 3GPP), such as a lower layer functional split. In such an architecture, each RU 340 can be operated to handle over the air (OTA) communication with one or more UEs 120. In some implementations, real-time and non-real-time aspects of control and user plane communication with the RU(s) 340 can be controlled by the corresponding DU 330. In some scenarios, this configuration can enable each DU 330 and the CU 310 to be implemented in a cloud-based RAN architecture, such as a vRAN architecture.

The SMO Framework 305 may be configured to support RAN deployment and provisioning of non-virtualized and virtualized network elements. For non-virtualized network elements, the SMO Framework 305 may be configured to support the deployment of dedicated physical resources for RAN coverage requirements, which may be managed via an operations and maintenance interface (such as an O1 interface). For virtualized network elements, the SMO Framework 305 may be configured to interact with a cloud computing platform (such as an open cloud (O-Cloud) platform 390) to perform network element life cycle management (such as to instantiate virtualized network elements) via a cloud computing platform interface (such as an O2 interface). Such virtualized network elements can include, but are not limited to, CUs 310, DUs 330, RUs 340, non-RT RICs 315, and Near-RT RICs 325. In some implementations, the SMO Framework 305 can communicate with a hardware aspect of a 4G RAN, such as an open eNB (O-eNB) 311, via an O1 interface. Additionally, in some implementations, the SMO Framework 305 can communicate directly with each of one or more RUs 340 via a respective O1 interface. The SMO Framework 305 also may include a Non-RT RIC 315 configured to support functionality of the SMO Framework 305.

The Non-RT RIC 315 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 325. The Non-RT RIC 315 may be coupled to or communicate with (such as via an A1 interface) the Near-RT RIC 325. The Near-RT RIC 325 may be configured to include a logical function that enables near-real-time control and optimization of RAN elements and resources via data collection and actions over an interface (such as via an E2 interface) connecting one or more CUs 310, one or more DUs 330, or both, as well as an O-eNB, with the Near-RT RIC 325.

In some implementations, to generate AI/ML models to be deployed in the Near-RT RIC 325, the Non-RT RIC 315 may receive parameters or external enrichment information from external servers. Such information may be utilized by the Near-RT RIC 325 and may be received at the SMO Framework 305 or the Non-RT RIC 315 from non-network data sources or from network functions. In some examples, the Non-RT RIC 315 or the Near-RT RIC 325 may be configured to tune RAN behavior or performance. For example, the Non-RT RIC 315 may monitor long-term trends and patterns for performance and employ AI/ML models to perform corrective actions through the SMO Framework 305 (such as reconfiguration via an O1 interface) or via creation of RAN management policies (such as A1 interface policies).

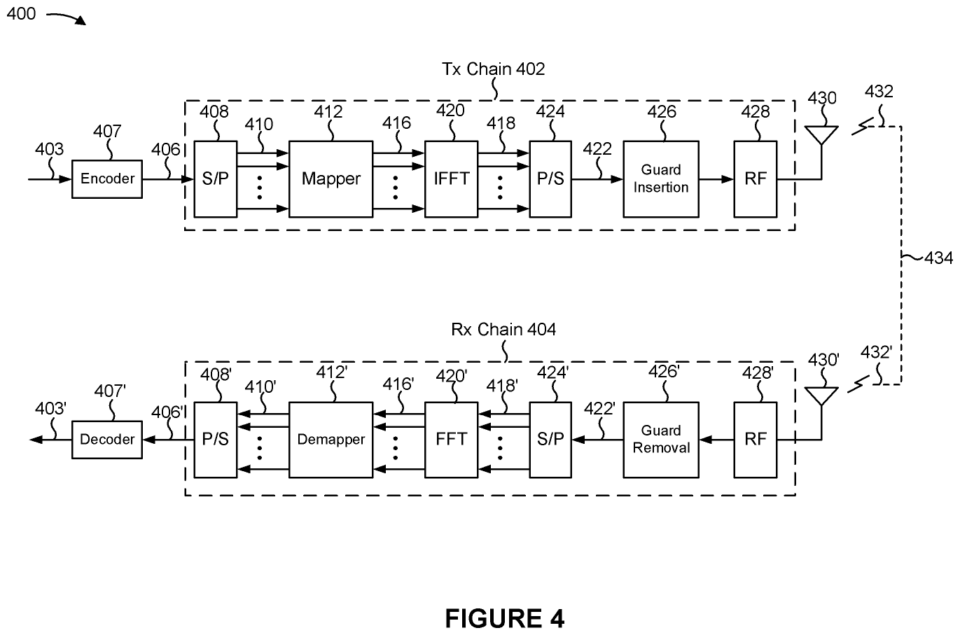

FIG. 4 is a diagram illustrating an example 400 of a transmit (Tx) chain 402 and a receive (Rx) chain 404 of a UE 120 in accordance with the present disclosure. In some aspects, one or more components of Tx chain 402 may be implemented in transmit processor 264, TX MIMO processor 266, modem 254, or controller/processor 280, as described above in connection with FIG. 2. In some examples, Tx chain 402 may be implemented in UE 120 for transmitting data 406 (for example, uplink data, an uplink reference signal, or uplink control information) to a network node 110 on an uplink channel.

An encoder 407 may alter a signal (for example, a bitstream) 403 into data 406. Data 406 to be transmitted is provided from encoder 407 as input to a serial-to-parallel (S/P) converter 408. In some examples, S/P converter 408 may split the transmission data into N parallel data streams 410.

The N parallel data streams 410 may then be provided as input to a mapper 412. Mapper 412 may map the N parallel data streams 410 onto N constellation points. The mapping may be done using a modulation constellation, such as amplitude shift keying (ASK), binary phase-shift keying (BPSK), quadrature phase-shift keying (QPSK), 8 phase-shift keying (8PSK), or quadrature amplitude modulation (QAM), among other examples. Thus, mapper 412 may output N parallel symbol streams 416, each symbol stream 416 corresponding to one of N orthogonal subcarriers of an inverse fast Fourier transform (IFFT) component 420. These N parallel symbol streams 416 are represented in the frequency domain and may be converted into N parallel time domain sample streams 418 by IFFT component 420.

In some examples, N parallel modulations in the frequency domain correspond to N modulation symbols in the frequency domain, which are equal to N mapping and N-point IFFT in the frequency domain, which are equal to one (useful) OFDM symbol in the time domain, which are equal to N samples in the time domain. One OFDM symbol in the time domain, Ns, is equal to Ncp (the number of guard samples per OFDM symbol)+N (the number of useful samples per OFDM symbol).

The N parallel time domain sample streams 418 may be converted into an OFDM/OFDMA symbol stream 422 by a parallel-to-serial (P/S) converter 424. A guard insertion component 426 may insert a guard interval between successive OFDM/OFDMA symbols in the OFDM/OFDMA symbol stream 422. The output of guard insertion component 426 may then be upconverted to a desired transmit frequency band by an RF front end 428. An antenna 430 may then transmit the resulting signal 432.

In some examples, Rx chain 404 may utilize OFDM/OFDMA. In some examples, one or more components of Rx chain 404 may be implemented in receive processor 258, MIMO detector 256, modem 254, or controller/processor 280, as described above in connection with FIG. 2. In some examples, Rx chain 404 may be implemented in UE 120 for receiving data 406 (for example, downlink data, a downlink reference signal, or downlink control information) from a network node 110 on a downlink channel.

A transmitted signal 432 is shown traveling over a wireless channel 434 from Tx chain 402 to Rx chain 404. When a signal 432′ is received by an antenna 430′, the received signal 432′ may be downconverted to a baseband signal by an RF front end 428′. A guard removal component 426′ may then remove the guard interval that was inserted between OFDM/OFDMA symbols by guard insertion component 426.

The output of guard removal component 426′ may be provided to an S/P converter 424′. The output may include an OFDM/OFDMA symbol stream 422′, and S/P converter 424′ may divide the OFDM/OFDMA symbol stream 422′ into N parallel time-domain symbol streams 418′, each of which corresponds to one of the N orthogonal subcarriers. A FFT component 420′ may convert the N parallel time-domain symbol streams 418′ into the frequency domain and output N parallel frequency-domain symbol streams 416′.

A demapper 412′ may perform the inverse of the symbol mapping operation that was performed by mapper 412, thereby outputting N parallel data streams 410′. A P/S converter 408′ may combine the N parallel data streams 410′ into a single data stream 406′. Ideally, data stream 406′ corresponds to data 406 that was provided as input to Tx chain 402. Data stream 406′ may be decoded into a decoded data stream 403′ by decoder 407′.

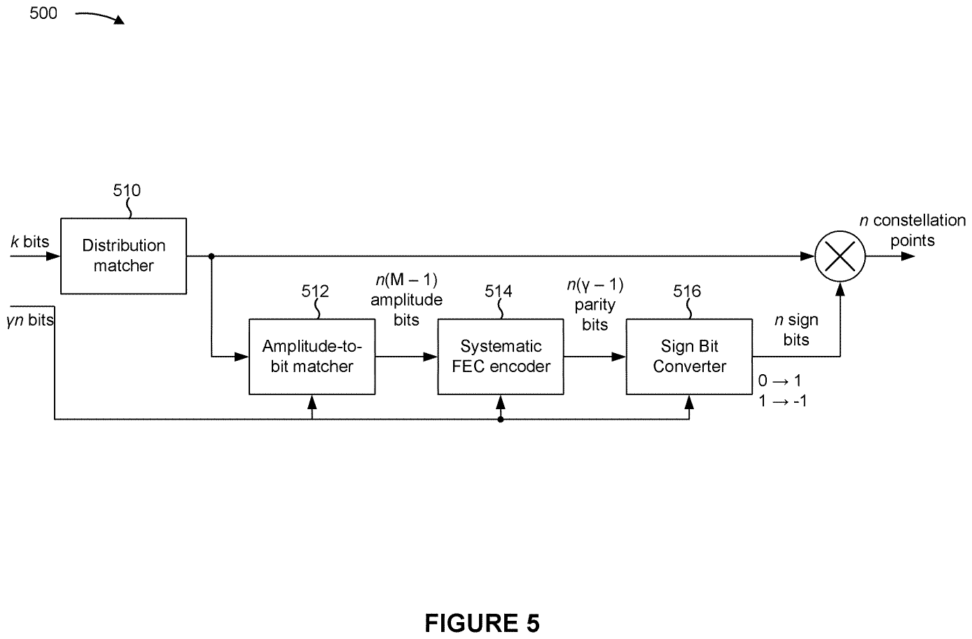

FIG. 5 is a diagram illustrating an example transmit chain 500 for probabilistic amplitude shaping in accordance with the present disclosure.

As shown in FIG. 5, the transmit chain 500 includes a distribution matcher 510, an amplitude-to-bit mapper 512, a systematic FEC encoder 514, and a sign bit converter 516. The transmit chain 500 may be used for, for example, ASK modulation with ASK constellations having a modulation order 2^{M}. An ASK constellation for the modulation order 2^{M} may include a set of constellation points {±1, ±3, . . . , ±(2^{M}−1)}. In some examples, the transmit chain 500 may have a transmission rate R_{c}=R_{dm}+γ, where R_{dm} represents a rate of the distribution matcher 510 and γ represents a set of parity bits that are added the k information bits that are to be encoded.

The ASK constellations may be associated with an amplitude alphabet of {1, 3, . . . , (2^{M}−1)}. The amplitude alphabet can include the set of possible constellation points (for example, without sign) from which the set of constellation points is generated. For example, an amplitude alphabet [symbol] ₘ={a₁, a₂, . . . , aₘ} of size m>1 may be configured for the transmit chain 500, with each element of [symbol] ₘ being referred to as a symbol. [symbol] ₘ may be constrained such that each element is ordered within [symbol] ₘ (for example, a₁<a₂< . . . <aₘ for any aᵢ). A symbol may have an energy E(aᵢ) for each value of i within the alphabet [symbol] ₘ. Based on the aforementioned constraint, symbol energies are ordered in correspondence with the ordering of symbols within [symbol] ₘ, such that 0; E(aᵢ)<E(aᵢ₊₁). For a 2^{M}-ary ASK constellation, described in FIG. 5, [symbol] ₘ={1, 3, . . . , 2^{M}−1}, where m=2^{M}−1 and {−1, 1}× [symbol] ₘ corresponds to the 2^{M}-ary constellation. In this example, aᵢ=2i−1 so that a₁=1, a₂=3, . . . , aₘ=2^{M}−1 and so that, for each i, the energy E(aᵢ)=(2i−1)² of symbol aᵢ, in a first example, or

$$E ( {a}_{i} ) = \frac{i ( i - 1 )}{2} ,$$

in a second example. In these two examples, the second example is a rescaling of the (2i−1)² term in the first example.

For the alphabet [symbol] ₘ of size m with a symbol sequence s=(s₁, s₂, . . . , sₙ) of length n, where each element of s is selected from [symbol] ₘ, the energy E(s) is an accumulation (for example, a sum) of all symbol energies of the symbol sequence

$$E ( s ) = {\sum }_{l = 1}^{n} E ( {s}_{l} ) .$$

Accordingly, for the 2^{M}-ary ASK constellation with M=3; [symbol] ₘ={1, 3, 5, 7}; and m=4, an example symbol sequence (5, 1, 1, 3, 5, 7) with length n=6 can be configured. For the example symbol sequence, symbol energies can be determined, for E(1)=1, E(3)=9, E(5)=25 and E(7)=49, such that E(s)=2E(1)+E(3)+2E(5)+E(7)=2+9+50+49=110. In another example, for E(1)=0, E(3)=1, E(5)=3 and E(7)=6, the symbol energies can be determined as E(s)=2E(1)+E(3)+2E(5)+E(7)=13.

As further shown in FIG. 5, the distribution matcher 510 may receive k information bits and map the k information bits to n amplitude symbols. The distribution matcher 510 may have a rate R_{dm}=k/n. In some examples, the distribution matcher 510 maps the information bits to the amplitude symbols to achieve a non-uniform distribution over the amplitude symbols. The non-uniform distribution induced by the distribution matcher 510 may be closer to a capacity-achieving input distribution than is achieved by a uniform distribution. In other words, the non-uniform distribution induced by the distribution matcher 510 is a probability distribution (for example, a Maxwell-Boltzmann (MB) distribution) in an additive white Gaussian noise (AWGN) channel. The transmit chain 500 may pass the n amplitude symbols to the amplitude-to-bit mapper 512, which may map the n amplitude symbols to a set of n(M−1) amplitude bits. The transmit chain 500 may pass the n(M−1) amplitude bits and γn extra information bits (for example, FEC bits) to the systematic FEC encoder 514 for FEC encoding. In this example, the systematic FEC encoder 514 receives n(M−1+γ) bits as input with a rate of R_{c}=(M−1+γ)/M. The systematic FEC encoder 514 may generate a set of n(1−γ) parity bits at the rate R_{c}. The transmit chain 500 may pass the n(1−γ) parity bits and the γn extra information bits to the sign bit converter 516, which may generate a set of n sign bits. The sign bit converter 516 generates a sign bit “1” for a bit “0” and a sign bit “−1” for a bit “1”. The transmit chain 500 may perform pointwise multiplication to combine the n amplitude symbols with the n sign bits to generate a set of n constellation points.

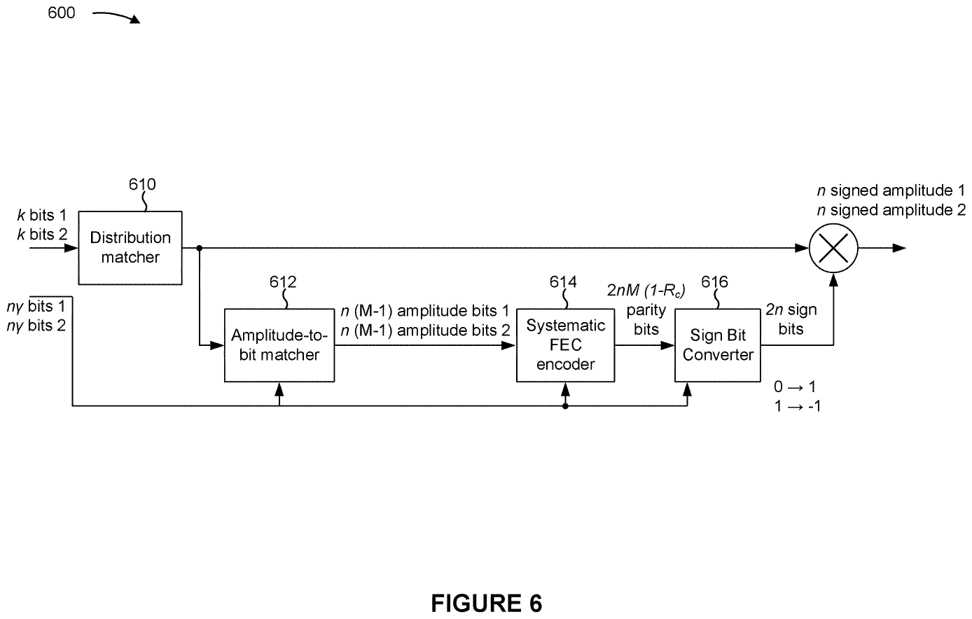

FIG. 6 is a diagram illustrating an example transmit chain 600 for probabilistic amplitude shaping in accordance with the present disclosure.

As shown in FIG. 6, the transmit chain 600 includes a distribution matcher 610, an amplitude-to-bit mapper 612, a systematic FEC encoder 614, and a sign bit converter 616. The transmit chain 600 may be used for, for example, QAM modulation with QAM constellations having a modulation order 2^{2M}. In such an example, a QAM constellation for the modulation order 2^{2M} may include a set of constellation points {±1, ±3, . . . , i(2^{M}−1)}×{±1, ±3, . . . , ±(2^{M}−1)}.

As further shown in FIG. 6, the distribution matcher 610 may receive a first set of k information bits and a second set of k information bits and maps the sets of k information bits to corresponding sets of n amplitude symbols. The transmit chain 600 may pass the sets of n amplitude symbols to the amplitude-to-bit mapper 612, which may map the sets of n amplitude symbols to a pair of sets of n(M−1) amplitude bits. The transmit chain 600 may pass the pair of sets of n(M−1) amplitude bits and a pair of sets of γn extra information bits to the systematic FEC encoder 614 for FEC encoding. The systematic FEC encoder 614 may have an FEC codeword length of n_{c}=n log₂(2^{2M})=2nM. In this example, the systematic FEC encoder 614 receives a total of 2└nMR_{c}┘ information bits as input in the form of two streams of n(M−1) amplitude bits from the information bits and two streams of extra information bits with each stream of extra information bits include nγ bits. The value for γ may be such that nγ=└nMR_{c}┘−n(M−1). Accordingly, the total number of bits for transmission B_{T}=2(k+└nMR_{c}┘−n(M−1)). The systematic FEC encoder 614 may generate a set of 2 nM(1−R_{c}) parity bits at the rate R_{c}. The transmit chain 600 may pass the 2 nM(1−R_{c}) parity bits and the pair of sets of γn extra information bits to the sign bit converter 616, which may generate a set of 2n sign bits. The transmit chain 600 may perform pointwise multiplication to combine the sets of n amplitude symbols with the 2n sign bits to generate a pair of sets of n signed amplitudes.

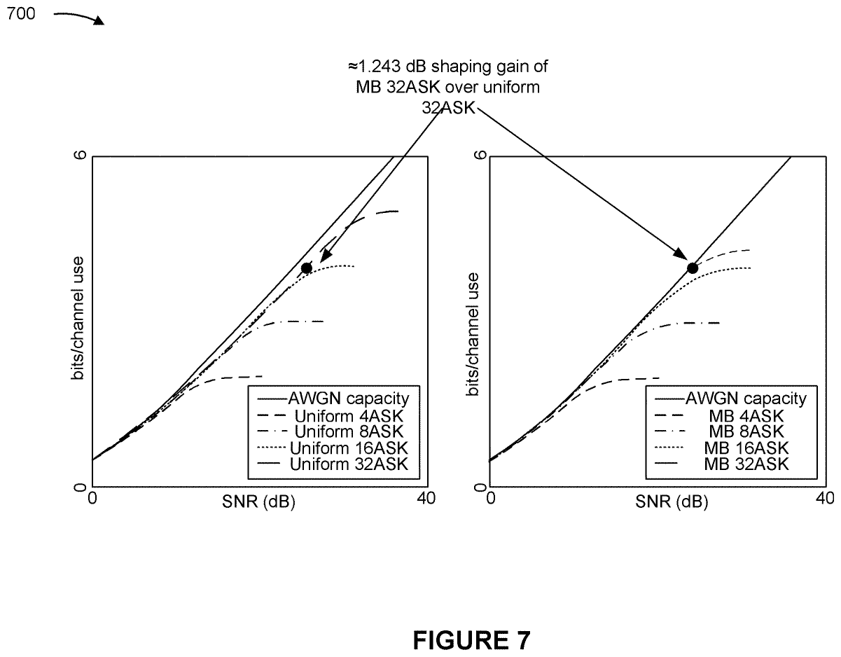

FIG. 7 is a diagram illustrating an example of shaping gain over an AWGN channel in accordance with the present disclosure.

A probability distribution (such as an MB distribution) with a parameter ν (a non-negative real number) over an amplitude alphabet [symbol] ₘ results in a probability distribution of the form

$${p}_{v} ( a ) = \frac{1}{{Z}_{v}} {e}^{- ν E ( a )} ,$$

where a represents elements of [symbol] ₘ and Z_{ν} is a normalizing constant. An optimal probability distribution over an ASK constellation, such as the ASK constellation described with reference to FIG. 5, can exhibit a relatively large shaping gain over a uniform distribution for the same constellation. In other words, the uniform distribution has a shaping gap of some amount from the optimal probability distribution (for example, an MB distribution). FIG. 7 shows a first example 700 of a uniform ASK distribution for 4-ASK through 32-ASK and a second example 710 of a probability distribution for 4-ASK through 32-ASK. As shown in examples 700 and 710, relative to an AWGN channel capacity, the probabilistic distribution (for example, an MB distribution) exhibits an approximately 1.243 dB shaping gain at, for example, 32-ASK modulation.

As described above, a set of encoded information bits may be associated with an amplitude alphabet [symbol] ₘ, a symbol sequence s, a sequence length n, and a total energy E. An energy threshold Ē may represent a constraint on the total energy E, such that [symbol] (m,n,Ē) can represent the set of all symbol sequences of length n and over an alphabet [symbol] ₘ such that the energy of each sequence is at most equal to an energy threshold Ē. In this example, [symbol] (m,n,Ē)={s=(s₁, s₂, . . . , s)|sᵢ∈ [symbol] ₘ, ∀i, E(s)≤Ē}. A transmitter device may perform energy-based shaping to encode length-k information bit sequences u=(u₁, u₂, . . . , uₖ) to one of the symbol sequences [symbol] (m,n,Ē). Two example techniques for the encoding include a direct energy-based arithmetic coding (AC) method and a two-stage peeling method. A distribution matcher of the transmitter device, such as distribution matchers 510 and 610 can implement one of the aforementioned example techniques. In such examples, a distribution mapper induces an injective mapping from the set of all 2^{k} possible information bit sequences to [symbol] (m,n,E). A consequence of such encoding is unique decodability is guaranteed at the receiver device by imposing conditions on k in terms of m, n, and Ē.

When a transmitter device is to encode a set of information bits for transmission on a channel with a particular SNR value, the transmitter device may have a target modulation order and an optimal distribution (such as an MB distribution) with a parameter ν, as described above. To enable mapping of the set of information bits to a symbol sequence, the transmitter device determines the energy threshold Ē that constrains which symbol sequence is to map to the information bits. Various aspects relate generally to determining the energy threshold for energy-based probabilistic amplitude shaping. Some aspects more specifically relate to determining an energy threshold based on the amplitude alphabet, the parameter ν, and an amplitude sequence length n. In some aspects, a transmitter device may use a polynomial representation or a table-based representation of a normalized energy threshold ω̅^{[m]} to determine the energy threshold Ē. Based on determining the energy threshold Ē, the transmitter device can apply energy-based encoding for amplitude shaping of a plurality of information bits to generate a set of symbols for transmission.

Particular aspects of the subject matter described in this disclosure can be implemented to realize one or more of the following potential advantages. In some examples, the described techniques can be used to minimize a shaping gap. By determining an energy threshold, such that a non-uniform distribution over a set of amplitude symbols induced by an energy-shaping scheme for amplitude shaping of a plurality of input bits is as close to an optimal distribution (such as an MB distribution) as possible, the transmitter device reduces a size of the shaping gap relative to other techniques for probabilistic amplitude shaping. In some example, the transmitter device may improve communication performance. For example, based on minimizing or reducing a shaping gap, the transmitter device increases a likelihood that a set of symbols are successfully transmitted to and decoded by a receiver device. This may reduce an amount of network traffic by reducing a quantity of retransmissions that are triggered for dropped or unsuccessfully decoded symbols.

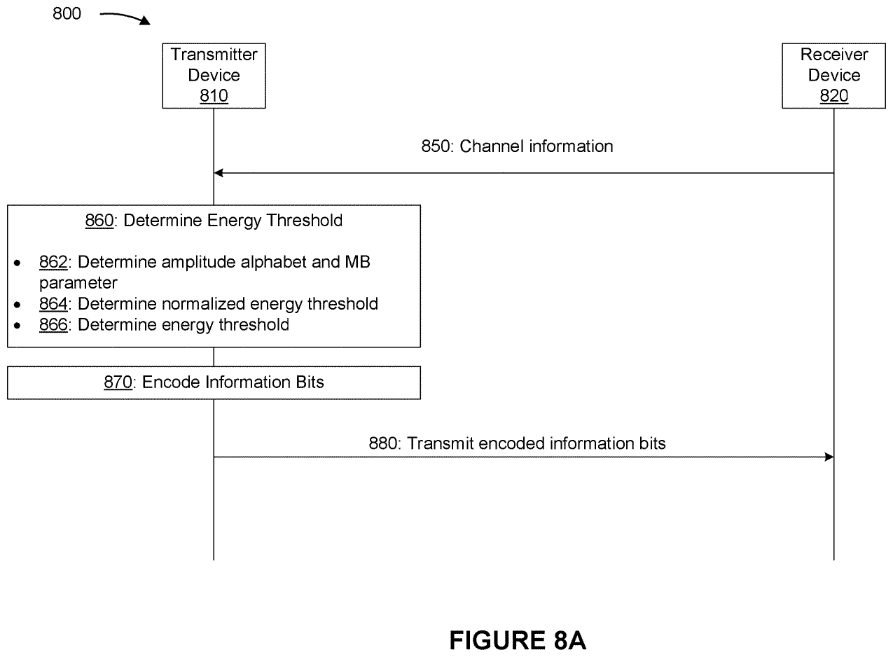

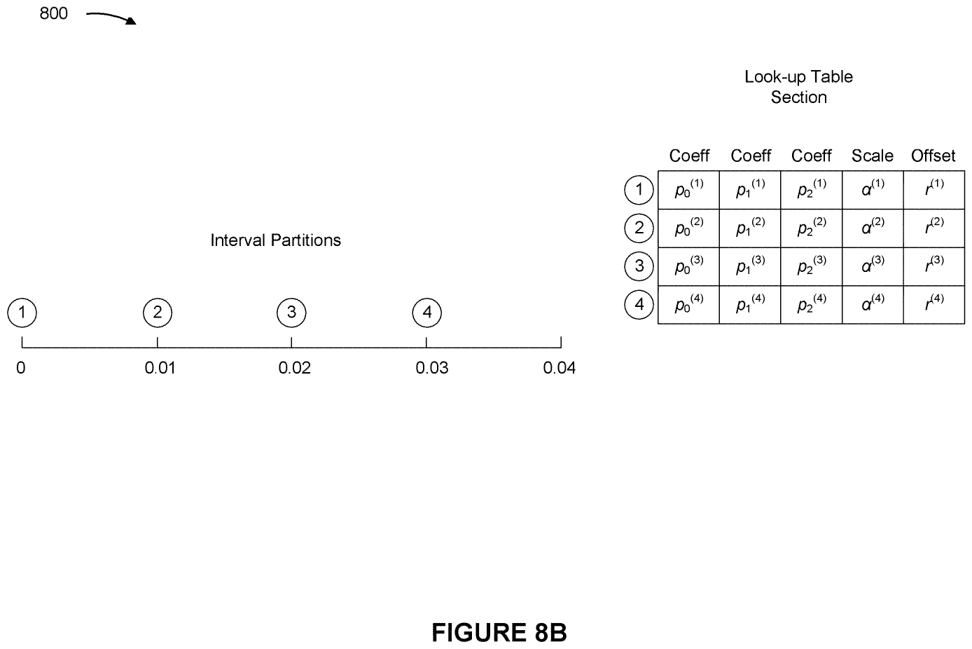

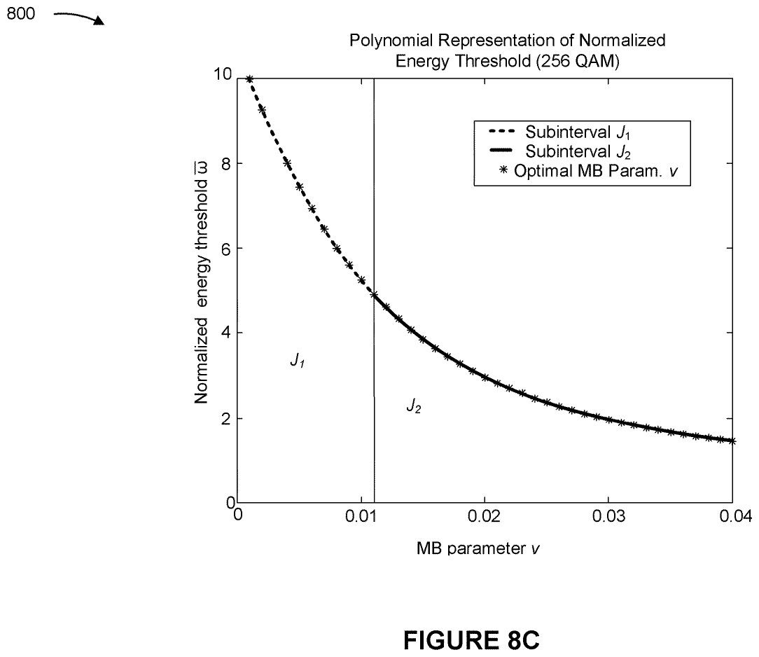

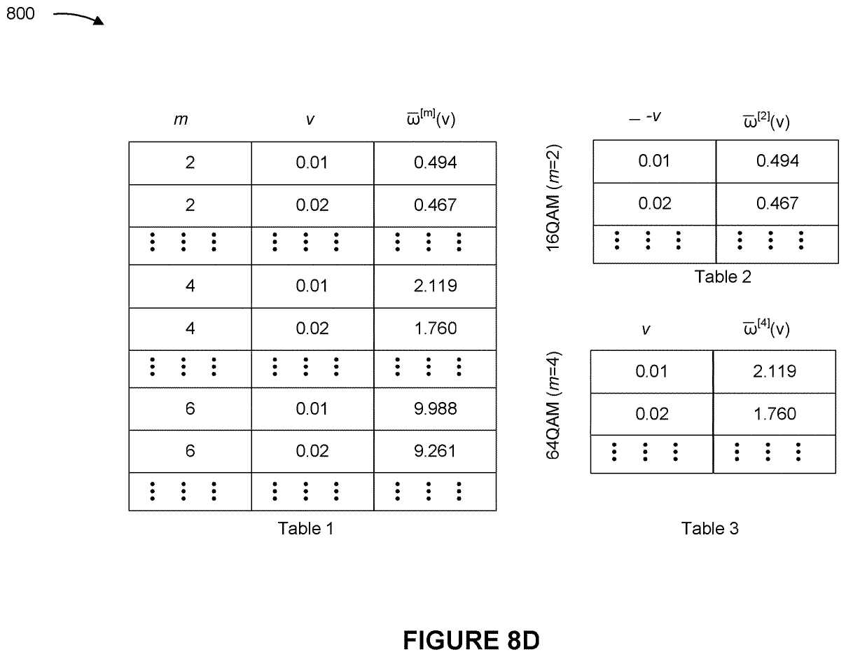

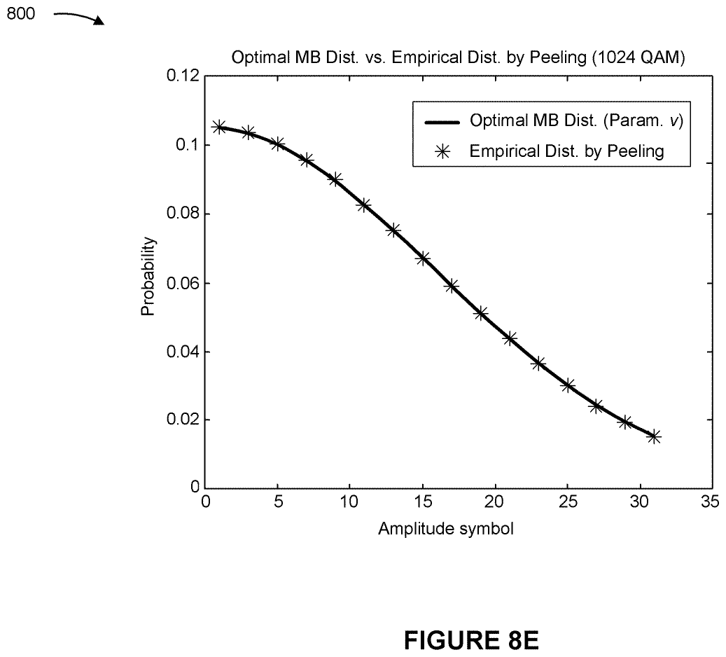

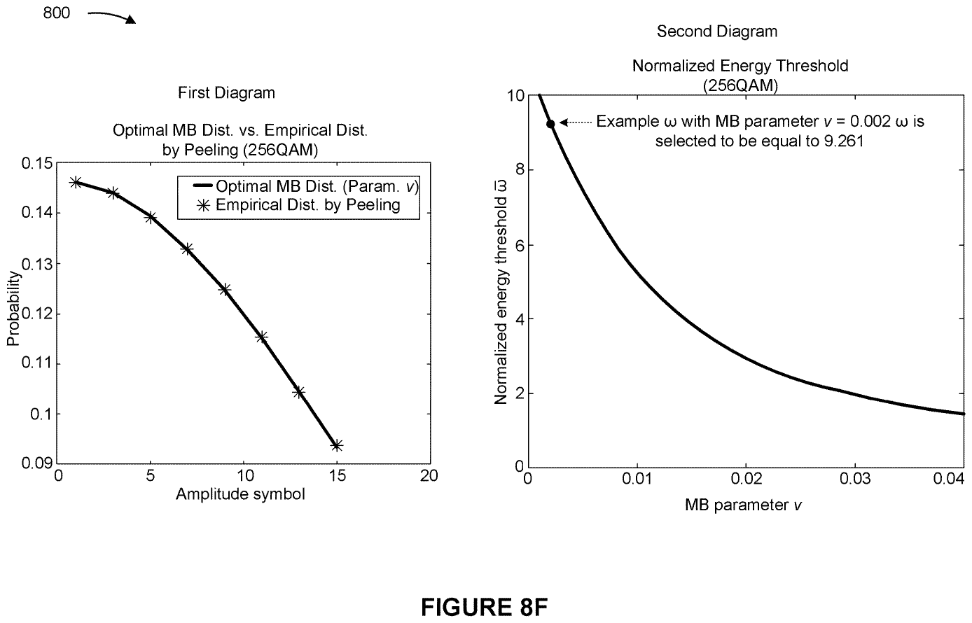

FIGS. 8A-8F are diagrams illustrating examples associated with energy threshold configuration in energy-based probabilistic amplitude shaping in accordance with the present disclosure. As shown in FIG. 8A, an example 800 includes communication between a transmitter device 810 and a receiver device 820. In some aspects, the transmitter device 810 may correspond to a UE 120 and the receiver device 820 may correspond to a network node 110. However, it is contemplated that the transmitter device 810 may correspond to a network node 110 or another device or that the receiver device 820 may correspond to a UE 120 or another device.

As further shown in FIG. 8A, and by a first operation 850, in some aspects, the transmitter device 810 may obtain channel information. For example, the transmitter device 810 may receive channel information from the receiver device 820. In some aspects, the channel information may include information associated with selecting a target modulation order and an optimal distribution parameter ν (which may be an MB distribution parameter). For example, the transmitter device 810 may receive information identifying an SNR value for a channel used for communication with the receiver device 820. In some aspects, the receiver device 820 may transmit a reference signal to the transmitter device 810 and the transmitter device 810 may perform a channel measurement. Additionally or alternatively, the transmitter device 810 may transmit a reference signal to the receiver device 820, which may perform a channel measurement and report the channel measurement as channel information to the transmitter device 810.

As further shown in FIG. 8A, and by a second operation 860, the transmitter device 810 may determine an energy threshold. For example, the transmitter device 810 may determine an amplitude alphabet [symbol] ₘ and a distribution parameter ν, at sub-operation 862, determine a normalized energy threshold ω̅^{[m]}(ν), at sub-operation 864, and determine the energy threshold Ē, at sub-operation 866. In some aspects, the transmitter device 810 may transmit information identifying the energy threshold to the receiver device 820. For example, based on determining the energy threshold, as described below, the transmitter device 810 may transmit a reference signal associated with identifying a value of the energy threshold to enable the receiver device 820 to determine the same energy threshold that the transmitter device 810 has determined. In such an example, the receiver device 820 can use the energy threshold for decoding of the encoded information bits, as described below.

In some aspects, the transmitter device 810 may determine the energy threshold based on the channel information. For example, the transmitter device 810 may select the distribution parameter ν based on a modulation scheme and may select the modulation scheme based on the channel information. In such an example, the transmitter device 810 may select the modulation scheme based on, for example, an SNR, an RSRP, an RSRQ, or a quality of service (QoS), among other examples. For example, the transmitter device 810 may select an ASK modulation scheme or a QAM modulation scheme, among other examples. Similarly, the transmitter device 810 may select the amplitude alphabet based on the modulation scheme. For example, the transmitter device 810 may select an amplitude alphabet [symbol] ₘ corresponding to constellation points for the selected modulation scheme.

In some aspects, the transmitter device 810 may determine the normalized energy threshold ω̅ based on the amplitude alphabet [symbol] ₘ and the distribution parameter ν. For example, the normalized energy threshold is a function of m and ν, ω̅=ω̅^{[m]}(ν), which may take the form of ω̅=ω̅(ν) for a given amplitude alphabet. In such an example, the transmitter device 810 may determine the energy threshold for a particular sequence length n as Ē=nω̅^{[m]}(ν). In some aspects, the energy threshold Ē is bound by a set of values. For example, given that the amplitude alphabet and associated symbols are ordered, as described above, a minimum symbol energy and a maximum symbol energy associated with the amplitude alphabet are E(aᵢ) and E(aₘ), respectively. Based on the minimum symbol energy and the maximum symbol energy, a minimum energy and maximum energy of a length-n sequence over [symbol] ₘ is given as nE(a₁) and nE(aₘ), respectively. The energy threshold Ē is then nE(aᵢ)≤Ē≤nE(aₘ), and for Ē=an, nE(a₁)≤α≤nE(aₘ), where α is a parameter.

In some aspects, the transmitter device 810 may determine the normalized energy threshold ω̅ based on a polynomial representation. For example, the transmitter device 810 may evaluate a polynomial or piecewise polynomial to determine the normalized energy threshold ω̅, which may reduce a computing complexity relative to evaluating a characteristic formula for ω̅=ω̅(ν). In such an example, the range of the distribution parameter ν, for a given amplitude alphabet [symbol] ₘ is an interval [symbol] ^{[m]}=[υ^{[m]}, υ̅^{[m]), where a polynomial p̅≡p̅}^{[m]} of degree d≡d^{[m]} is used such that p̅(ν) approximates ω̅(ν). The polynomial p̅ is of the form

$$\overline{p} ( ν ) = {\sum }_{i = 0}^{d} {{p}_{i} ( {a}^{[ m ]} ν - {r}^{[ m ]} )}^{i} ,$$

where a≡a^{[m]} is a scaling factor, r≡r^{[m]} is an offset factor, and

$${p}_{i} ≡ {p}_{i}^{[ m ]}$$

is a coefficient corresponding to an i-th power term. The interval [symbol] is partionable into a set of subintervals with each sub-interval corresponding to a polynomial used to approximate ω̅ over the subinterval. In other words, a piecewise polynomial is constructed over the interval [symbol] to approximate ω̅.

In some aspects, the transmitter device 810 may use a set of look-up tables to evaluate the set of subintervals. For example, the transmitter device 810 may have a set of look-up tables storing sets of polynomial coefficients, scaling factors, and offset factors for the piecewise polynomial. In such an example, each possible amplitude alphabet [symbol] ₘ that the transmitter device 810 may use (for one or more modulation sch e hat the transmitter device 810 may select), may correspond to one or more look-up tables, with each row of the table corresponding to a piece of the piecewise polynomial. FIG. 8B shows an example of an interval [symbol] with values of ν from 0 to 0.04 partitioned into 4 partitions. As further shown in FIG. 8B, a section of a look-up table is shown with coefficients for the 4 partitions. In such an example, the look-up table stores values identifying a set of polynomial coefficients pₓ^{y}, a set of scaling factors α^{y}, and a set of offset values r^{y}, where x represents a polynomial coefficient term from 0 to 2 (corresponding to a polynomial degree of 3) and y represents an interval from 1 to 4. For a determined amplitude alphabet [symbol] ₘ and a distribution parameter ν, the transmitter device 810 determines which subinterval of [symbol] contains ν and uses a subinterval index of the subinterval to obtain polynomial coefficients, a scaling factor, and an offset factor for constructed a piece of the piecewise polynomial. The transmitter device 810 evaluates the piece of the piecewise polynomial to determine the normalized energy threshold ω̅.

In the above case, even for a relatively small polynomial degree d, p̅(ν) can approximate ω̅(ν) with a threshold level of accuracy, thereby providing a low-complexity determination of the normalized energy threshold ω̅ and, from the normalized energy threshold ω̅, a low-complexity determination of the energy threshold Ē from ω̅ and for a determined ν and sequence length n. FIG. 8C shows an example of using a piecewise polynomial representation. For example, for 256-QAM, an interval [symbol] =[υ, υ̅]=[0.001, 0.04] is partitioned into two subintervals [symbol] ₁=[0.001, 0.015) and [symbol] ₂=[0.015, 0.04]. For [symbol] ₁, a polynomial degree of 5 is selected with a scaling factor set to 20 and an offset factor set to 0.02. For [symbol] ₂, a polynomial degree of 4 is selected with a scaling factor of 20 and an offset factor of 0.3. As shown in FIG. 8C, the resulting piecewise polynomial for the interval [symbol] closely matches an optimal distribution parameter ν, thereby enabling the transmitter device 810 to select a parameter ν relatively close to the optimal distribution parameter ν using the piecewise polynomial.

In some aspects, the transmitter device 810 may use a tabulation method for determining the normalized energy threshold ω̅. For example, the transmitter device 810 may store a look-up table storing values for m, ν, and ω^{[m]}(ν), as shown in FIG. 8D, and by Table 1. Here, the transmitter device 810 can take a value for m and a value for ν to determine a value for ω̅^{[m]}(ν), from which the transmitter device 810 can determine Ē. In another example, rather than storing values for m, ν, and ω̅^{[m]}(ν), the single look-up table can store values for a modulation scheme, ν, and ω̅^{[m]}(ν). In such an example, the transmitter device 810 can take a determined modulation scheme and a value for ν to determine ω̅^{[m]}(ν), from which the transmitter device 810 can determine Ē. In yet another example, rather than a single look-up table, the transmitter device 810 may have a plurality of look-up tables. For example, the transmitter device 810 may have a look-up table corresponding to each value for m or each modulation scheme and having values for ν and ω̅^{[m]}(ν), as shown in FIG. 8D and by Tables 2 (for 16-QAM and m=2) and 3 (for 64-QAM and m=4). Although a particular set of look-up tables are described it is contemplated that other types of look-up tables or other data structures may be possible.

Returning to FIG. 8A, and in a third operation 870, the transmitter device 810 may encode the set of information bits. For example, the transmitter device 810 may encode the set of information bits using an energy-shaping procedure to generate a symbol sequence based on the energy threshold.

FIG. 8E shows an example of an accuracy of using a polynomial method or tabulation method to determine Ē for energy-based shaping. In this example, the transmitter device 810 may encode a set of information bits using an energy-based shaping scheme for 1024-QAM with m=16, n=512, and ν=0.002. The example shows an empirical distribution of P₁₆ (the empirical distribution) over [symbol] ₁₆ (the amplitude alphabet for m=16) averaged across a sample of 10⁴ instances achieved using a two-stage Peeling encoder in accordance with a selected value for Ē (for example, selected with a polynomial method or a tabulation method). As shown, the empirical distribution closely matches an optimal distribution distribution over [symbol] ₁₆ with the distribution parameter (for example, an MB parameter) set to ν=0.002.

FIG. 8F, in the first diagram, shows another example of an accuracy of using the polynomial method or the tabulation method to determine Ē for energy-based shaping. In this example, the transmitter device 810 may encode a set of information bits using an energy-based shaping scheme for 256-QAM with m=8, n=256, and ν=0.002. In the second diagram of FIG. 8F, values for the distribution parameter ν are shown for different values of the normalized energy threshold ω̅, where ω̅ is a continuously differentiable function of ν. In such an example, for any value for the distribution parameter ν within the range of the second diagram (0 to 0.04), the corresponding value for ω̅ results in an average empirical distribution over [symbol] ₘ that is o(n⁻¹)-close to the optimal distribution (for example, an MB distribution) with parameter ν. In other words, for the selected value of ν=0.002 in the first diagram, the accuracy of the empirical distribution achieved by a two-stage Peeling encoder is o(n⁻¹)-close to the optimal distribution, thereby reducing or minimizing a shaping gap associated with energy-shaping.

As further shown in FIG. 8A, and in a fourth operation 880, the transmitter device 810 may transmit the encoded information bits. For example, the transmitter device 810 may transmit a set of symbols, conveying the set of information bits, to the receiver device 820. The receiver device 820 may receive the set of symbols and may decode the set of symbols to recover the information bits conveyed therein, thereby enabling communication from the transmitter device 810 to the receiver device 820. For example, the receiver device 820 may use the energy threshold, conveyed via a reference signal from the transmitter device 810, to decode the set of symbols into the set of information bits, as described above.

FIG. 9 is a flowchart illustrating an example process 900 performed, for example, by a transmitter device that supports energy threshold configuration in energy-based probabilistic amplitude shaping in accordance with the present disclosure. Example process 900 is an example where the transmitter device (for example, the ULE 120 or the transmitter device 810) performs operations associated with energy threshold configuration in energy-based probabilistic amplitude shaping.

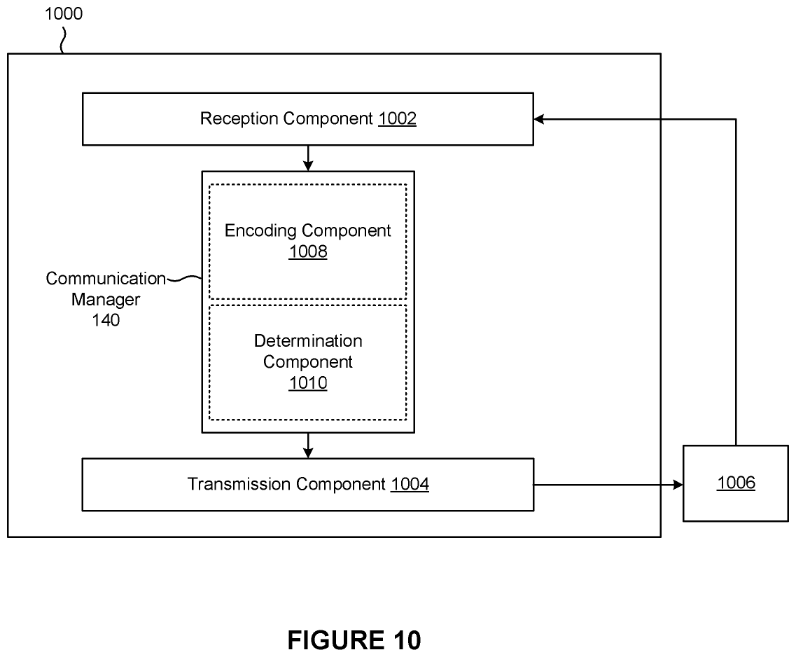

As shown in FIG. 9, in some aspects, process 900 may include determining an energy threshold based on a normalized energy threshold and an amplitude sequence length, the normalized energy threshold being based on an amplitude alphabet and a distribution parameter (block 910). For example, the transmitter device (such as by using communication manager 140 or determination component 1010, depicted in FIG. 10) may determine an energy threshold based on a normalized energy threshold and an amplitude sequence length, the normalized energy threshold being based on an amplitude alphabet and a distribution parameter, as described above.

As further shown in FIG. 9, in some aspects, process 900 may include encoding a plurality of information bits into a symbol sequence with amplitude shaping, the encoding being based on the energy threshold, the amplitude alphabet, and the amplitude sequence length (block 920). For example, the transmitter device (such as by using communication manager 140 or encoding component 1008, depicted in FIG. 10) may encode a plurality of information bits into a symbol sequence with amplitude shaping, the encoding being based on the energy threshold, the amplitude alphabet, and the amplitude sequence length, as described above.

As further shown in FIG. 9, in some aspects, process 900 may include transmitting the symbol sequence encoded with amplitude shaping, the symbol sequence having a length equal to the amplitude sequence length and each symbol, of the symbol sequence, corresponding to an entry in the amplitude alphabet (block 930). For example, the transmitter device (such as by using communication manager 140 or transmission component 1004, depicted in FIG. 10) may transmit the symbol sequence encoded with amplitude shaping, the symbol sequence having a length equal to the amplitude sequence length and each symbol, of the symbol sequence, corresponding to an entry in the amplitude alphabet, as described above.

Process 900 may include additional aspects, such as any single aspect or any combination of aspects described below or in connection with one or more other processes described elsewhere herein.

In a first additional aspect, process 900 includes transmitting information identifying the energy threshold to a receiver device based on determining the energy threshold.

In a second additional aspect, alone or in combination with the first aspect, the distribution parameter is a Maxwell-Boltzmann parameter associated with a probability distribution over the symbol sequence.

In a third additional aspect, alone or in combination with one or more of the first and second aspects, the distribution parameter is in a range that is associated with the amplitude alphabet and the modulation order.

In a fourth additional aspect, alone or in combination with one or more of the first through third aspects, process 900 includes receiving information identifying a modulation scheme for transmitting the symbol sequence, and determining at least one of the amplitude alphabet or the distribution parameter based on the modulation scheme.

In a fifth additional aspect, alone or in combination with one or more of the first through fourth aspects, process 900 includes determining the normalized energy threshold based on a polynomial representation or a tabulation representation.

In a sixth additional aspect, alone or in combination with one or more of the first through fifth aspects, the polynomial representation is associated with a lookup table storing a plurality of sets of polynomial coefficients, a set of scaling factors, and a set of offset factors, and wherein the normalized energy threshold is based on a respective set of polynomial coefficients of the plurality of sets of polynomial coefficients, a respective scaling factor of the set of scaling factors, and a respective offset factor of the set of offset factors.

In a seventh additional aspect, alone or in combination with one or more of the first through sixth aspects, indices of the lookup table correspond to polynomial coefficients of the plurality of sets of polynomial coefficients.

In an eighth additional aspect, alone or in combination with one or more of the first through seventh aspects, the normalized energy threshold is associated with a value of a polynomial, associated with a set of polynomial coefficients, of the plurality of sets of polynomial coefficients, corresponding to a sub-interval, of an interval, that includes the distribution parameter.

In a ninth additional aspect, alone or in combination with one or more of the first through eighth aspects, the interval is associated with the amplitude alphabet.

In a tenth additional aspect, alone or in combination with one or more of the first through ninth aspects, the tabulation representation is associated with a single lookup table storing a set of amplitude alphabet values, a set of distribution parameters, and a set of normalized energy thresholds, the set of normalized energy thresholds corresponding to the set of amplitude alphabet values and the set of distribution parameters.

In an eleventh additional aspect, alone or in combination with one or more of the first through tenth aspects, the tabulation representation is associated with a single lookup table storing a set of modulation order values, a set of distribution parameters, and a set of normalized energy thresholds, the set of normalized energy thresholds corresponding to the set of modulation order values and the set of distribution parameters.

In a twelfth additional aspect, alone or in combination with one or more of the first through eleventh aspects, the tabulation representation is associated with a plurality of lookup tables for a plurality of amplitude alphabet values or a plurality of modulation orders, and wherein a lookup table, of the plurality of lookup tables, associated with an amplitude alphabet value, of the plurality of amplitude alphabet values, or a modulation order, of the plurality of modulation orders, stores a set of distribution parameters and stores a set of normalized energy thresholds, the set of normalized energy thresholds corresponding to the set of distribution parameters and corresponding to the amplitude alphabet value or the modulation order.

Although FIG. 9 shows example blocks of process 900, in some aspects, process 900 may include additional blocks, fewer blocks, different blocks, or differently arranged blocks than those depicted in FIG. 9. Additionally or alternatively, two or more of the blocks of process 900 may be performed in parallel.

FIG. 10 is a diagram of an example apparatus 1000 for wireless communication that supports energy threshold configuration in energy-based probabilistic amplitude shaping in accordance with the present disclosure. The apparatus 1000 may be a transmitter device, or a transmitter device may include the apparatus 1000. For example, the apparatus 1000 may be a UE 120. Although some aspects are described herein in terms of a transmitter device being a UE 120, it is contemplated that the transmitter device may be another type of wireless communication device, such as a network node 110, an extended reality (XR) device, or a component of a disaggregated base station architecture, among other examples. In some aspects, the apparatus 1000 includes a reception component 1002, a transmission component 1004, and a communication manager 140, which may be in communication with one another (for example, via one or more buses). As shown, the apparatus 1000 may communicate with another apparatus 1006 (such as a UE, a network node, or another wireless communication device) using the reception component 1002 and the transmission component 1004.

In some aspects, the apparatus 1000 may be configured to perform one or more operations described herein in connection with FIGS. 8A-8F. Additionally or alternatively, the apparatus 1000 may be configured to perform one or more processes described herein, such as process 900 of FIG. 9. In some aspects, the apparatus 1000 may include one or more components of the transmitter device described above in connection with FIG. 2.

The reception component 1002 may receive communications, such as reference signals, control information, or data communications, from the apparatus 1006. The reception component 1002 may provide received communications to one or more other components of the apparatus 1000, such as the communication manager 140. In some aspects, the reception component 1002 may perform signal processing on the received communications (such as filtering, amplification, demodulation, analog-to-digital conversion, demultiplexing, deinterleaving, de-mapping, equalization, interference cancellation, or decoding, among other examples), and may provide the processed signals to the one or more other components. In some aspects, the reception component 1002 may include one or more antennas, a modem, a demodulator, a MIMO detector, a receive processor, a controller/processor, or a memory of the transmitter device described above in connection with FIG. 2.

The transmission component 1004 may transmit communications, such as reference signals, control information, or data communications, to the apparatus 1006. In some aspects, the communication manager 140 may generate communications and may transmit the generated communications to the transmission component 1004 for transmission to the apparatus 1006. In some aspects, the transmission component 1004 may perform signal processing on the generated communications (such as filtering, amplification, modulation, digital-to-analog conversion, multiplexing, interleaving, mapping, or encoding, among other examples), and may transmit the processed signals to the apparatus 1006. In some aspects, the transmission component 1004 may include one or more antennas, a modem, a modulator, a transmit MIMO processor, a transmit processor, a controller/processor, or a memory of the transmitter device described above in connection with FIG. 2. In some aspects, the transmission component 1004 may be co-located with the reception component 1002 in a transceiver.

The communication manager 140 may determine an energy threshold based on a normalized energy threshold and an amplitude sequence length, the normalized energy threshold being based on an amplitude alphabet and a distribution parameter. The communication manager 140 may encode a plurality of information bits into a symbol sequence with amplitude shaping, the encoding being based on the energy threshold, the amplitude alphabet, and the amplitude sequence length. The communication manager 140 may transmit or may cause the transmission component 1004 to transmit the symbol sequence encoded with amplitude shaping, the symbol sequence having a length equal to the amplitude sequence length and each symbol, of the symbol sequence, corresponding to an entry in the amplitude alphabet. In some aspects, the communication manager 140 may perform one or more operations described elsewhere herein as being performed by one or more components of the communication manager 140.

The communication manager 140 may include a controller/processor or a memory of the transmitter device described above in connection with FIG. 2. In some aspects, the communication manager 140 includes a set of components, such as an encoding component 1008 or a determination component 1010. Alternatively, the set of components may be separate and distinct from the communication manager 140. In some aspects, one or more components of the set of components may include or may be implemented within a controller/processor or a memory of the transmitter device described above in connection with FIG. 2. Additionally or alternatively, one or more components of the set of components may be implemented at least in part as software stored in a memory. For example, a component (or a portion of a component) may be implemented as instructions or code stored in a non-transitory computer-readable medium and executable by a controller or a processor to perform the functions or operations of the component.

The encoding component 1008 may encode a plurality of information bits into a symbol sequence with amplitude shaping based on an amplitude alphabet, an amplitude sequence length, and an energy threshold, the energy threshold being based on a normalized energy threshold and the amplitude sequence length, the normalized energy threshold being based on the amplitude alphabet and a distribution parameter. The transmission component 1004 may transmit the symbol sequence encoded with amplitude shaping, the symbol sequence having a length equal to the amplitude sequence length and each symbol, of the symbol sequence, corresponding to an entry in the amplitude alphabet.

The determination component 1010 may determine the energy threshold based on the normalized energy threshold and the amplitude sequence length, wherein encoding the plurality of information bits comprises encoding the plurality of information bits based on determining the energy threshold. The reception component 1002 may receive information identifying a modulation scheme for transmitting the symbol sequence. The determination component 1010 may determine at least one of the amplitude alphabet or the distribution parameter based on the modulation scheme. The determination component 1010 may determine the normalized energy threshold based on a polynomial representation or a tabulation representation.

The number and arrangement of components shown in FIG. 10 are provided as an example. In practice, there may be additional components, fewer components, different components, or differently arranged components than those shown in FIG. 10. Furthermore, two or more components shown in FIG. 10 may be implemented within a single component, or a single component shown in FIG. 10 may be implemented as multiple, distributed components. Additionally or alternatively, a set of (one or more) components shown in FIG. 10 may perform one or more functions described as being performed by another set of components shown in FIG. 10.

The following provides an overview of some Aspects of the present disclosure:

Aspect 1: A method of wireless communication performed by an apparatus of a transmitter device, comprising: determining an energy threshold based on a normalized energy threshold and an amplitude sequence length, the normalized energy threshold being based on an amplitude alphabet and a distribution parameter; encoding a plurality of information bits into a symbol sequence with amplitude shaping, the encoding being based on the energy threshold, the amplitude alphabet, and the amplitude sequence length; and transmitting the symbol sequence encoded with amplitude shaping, the symbol sequence having a length equal to the amplitude sequence length and each symbol, of the symbol sequence, corresponding to an entry in the amplitude alphabet.

Aspect 2: The method of Aspect 1, further comprising: transmitting information identifying the energy threshold to a receiver device based on determining the energy threshold.

Aspect 3: The method of any of Aspects 1 to 2, wherein the distribution parameter is a Maxwell-Boltzmann parameter associated with a probability distribution over the symbol sequence.

Aspect 4: The method of any of Aspects 1 to 3, wherein the distribution parameter is in a range that is associated with the amplitude alphabet and the modulation order.

Aspect 5: The method of any of Aspects 1 to 4, further comprising: receiving information identifying a modulation scheme for transmitting the symbol sequence; and determining at least one of the amplitude alphabet or the distribution parameter based on the modulation scheme.

Aspect 6: The method of any of Aspects 1 to 5, further comprising: determining the normalized energy threshold based on a polynomial representation or a tabulation representation.

Aspect 7: The method of Aspect 6, wherein the polynomial representation is associated with a lookup table storing a plurality of sets of polynomial coefficients, a set of scaling factors, and a set of offset factors, and wherein the normalized energy threshold is based on a respective set of polynomial coefficients of the plurality of sets of polynomial coefficients, a respective scaling factor of the set of scaling factors, and a respective offset factor of the set of offset factors.

Aspect 8: The method of Aspect 7, wherein indices of the lookup table correspond to polynomial coefficients of the plurality of sets of polynomial coefficients.

Aspect 9: The method of any of Aspects 6 to 8, wherein the normalized energy threshold is associated with a value of a polynomial, associated with a set of polynomial coefficients, of the plurality of sets of polynomial coefficients, corresponding to a sub-interval, of an interval, that includes the distribution parameter.

Aspect 10: The method of Aspect 9, wherein the interval is associated with the amplitude alphabet.

Aspect 11: The method of any of Aspects 6 to 10, wherein the tabulation representation is associated with a single lookup table storing a set of amplitude alphabet values, a set of distribution parameters, and a set of normalized energy thresholds, the set of normalized energy thresholds corresponding to the set of amplitude alphabet values and the set of distribution parameters.

Aspect 12: The method of any of Aspects 6 to 11, wherein the tabulation representation is associated with a single lookup table storing a set of modulation order values, a set of distribution parameters, and a set of normalized energy thresholds, the set of normalized energy thresholds corresponding to the set of modulation order values and the set of distribution parameters.

Aspect 13: The method of any of Aspects 6 to 12, wherein the tabulation representation is associated with a plurality of lookup tables for a plurality of amplitude alphabet values or a plurality of modulation orders, and wherein a lookup table, of the plurality of lookup tables, associated with an amplitude alphabet value, of the plurality of amplitude alphabet values, or a modulation order, of the plurality of modulation orders, stores a set of distribution parameters and stores a set of normalized energy thresholds, the set of normalized energy thresholds corresponding to the set of distribution parameters and corresponding to the amplitude alphabet value or the modulation order.

Aspect 14: An apparatus for wireless communication at a device, comprising a processor; memory coupled with the processor; and instructions stored in the memory and executable by the processor to cause the apparatus to perform the method of one or more of Aspects 1-13.

Aspect 15: A device for wireless communication, comprising a memory and one or more processors coupled to the memory, the one or more processors configured to perform the method of one or more of Aspects 1-13.

Aspect 16: An apparatus for wireless communication, comprising at least one means for performing the method of one or more of Aspects 1-13.

Aspect 17: A non-transitory computer-readable medium storing code for wireless communication, the code comprising instructions executable by a processor to perform the method of one or more of Aspects 1-13.

Aspect 18: A non-transitory computer-readable medium storing a set of instructions for wireless communication, the set of instructions comprising one or more instructions that, when executed by one or more processors of a device, cause the device to perform the method of one or more of Aspects 1-13.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise. As used herein, a “processor” is implemented in hardware or a combination of hardware and software. It will be apparent that systems or methods described herein may be implemented in different forms of hardware or a combination of hardware and software. The actual specialized control hardware or software code used to implement these systems or methods is not limiting of the aspects. Thus, the operation and behavior of the systems or methods are described herein without reference to specific software code, because those skilled in the art will understand that software and hardware can be designed to implement the systems or methods based, at least in part, on the description herein.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples.

Even though particular combinations of features are recited in the claims or disclosed in the specification, these combinations are not intended to limit the disclosure of various aspects. Many of these features may be combined in ways not specifically recited in the claims or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (for example, a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” and similar terms are intended to be open-ended terms that do not limit an element that they modify (for example, an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (for example, if used in combination with “either” or “only one of”).

1. An apparatus for wireless communication at a user equipment (UE) comprising:
a memory; and
at least one processor coupled to the memory and, based at least in part on information stored in the memory, the at least one processor is configured to:
measure a channel condition for each of a plurality of antennas at the UE; and
dynamically select, while in a radio resource control (RRC) idle mode, at least one antenna from the plurality of antennas based on the channel condition.

2. (canceled)

3. The apparatus of claim 1, wherein the channel condition for each of the plurality of antennas is measured during a measurement period, wherein measurement of the channel condition is based on at least one threshold.

4. The apparatus of claim 3, wherein the at least one threshold is configurable or pre-configured.

5. The apparatus of claim 3, wherein the at least one processor is configured to:
terminate the measurement of the channel condition for each of the plurality of inactive antennas in response to the channel condition on two active antennas being greater than a first threshold (T0) and a physical downlink shared channel (PDSCH) result comprises a cyclic redundancy check (CRC) pass rate of 100%.

6. The apparatus of claim 3, wherein the at least one processor is configured to:
trigger the measurement across the plurality of antennas in response to an imbalance of the channel condition between two active antennas being greater than a fourth threshold (T3).

7. (canceled)

8. The apparatus of claim 3, wherein the at least one processor is configured to:
trigger the measurement across the plurality of antennas in response to the channel condition across a first pair of active antennas is less than a second threshold (T1); and
determine whether a second pair of antennas have channel conditions greater than the second threshold.

9. (canceled)

10. The apparatus of claim 8, wherein the at least one processor is configured to:
switch to the second pair of antennas in response to the second pair of antennas comprising the channel conditions greater than the second threshold.

11. The apparatus of claim 3, wherein the at least one processor is configured to:
activate all antennas of the plurality of antennas to receive downlink signaling in response to the channel condition of the plurality of antennas being less than a third threshold (T2).

12. A method of wireless communication at user equipment (UE), comprising:
measuring a channel condition for each of a plurality of antennas at the UE; and
dynamically selecting, while in a radio resource control (RRC) idle mode, at least one antenna from the plurality of antennas based on the channel condition.

13. (canceled)

14. (canceled)

15. (canceled)

16. (canceled)

17. An apparatus for wireless communication at a user equipment (UE) comprising:
a memory; and
at least one processor coupled to the memory and, based at least in part on information stored in the memory, the at least one processor is configured to:
measure a channel condition for a first set of antennas and a second set of antennas at the UE; and
dynamically select, while in a radio resource control (RRC) idle mode, at least one antenna from the first set of antennas or the second set of antennas based on the channel condition.

18. (canceled)

19. The apparatus of claim 17, wherein the first set of antennas comprises two antennas and the second set of antennas comprises two antennas.

20. The apparatus of claim 19, wherein at least one of the first set of antennas or the second set of antennas is inactive, wherein measurement of the channel condition occurs while the at least one of the first set of antennas or the second set of antennas is inactive.

21. The apparatus of claim 20, wherein the measurement of the channel condition of an inactive set of the at least one of the first set of antennas or the second set of antennas is during a discontinuous reception (DRX) off period.

22. The apparatus of claim 19, wherein each of the first set of antennas or the second set of antennas is measured at least once during one or more DRX periods.

23. The apparatus of claim 22, wherein the one or more DRX periods comprise one or more idle DRX (I-DRX) periods, wherein measurement of the first set of antennas or the second set of antennas is triggered once every I-DRX period or multiple I-DRX periods, wherein a measurement rate is based on an RSRP level of an active set of the first set of antennas or the second set of antennas.

24. The apparatus of claim 19, wherein the at least one processor is configured to: remain on an active set of antennas from the first set of antennas or the second set of antennas in response to the channel condition being greater than a first threshold (T0) and a physical downlink shared channel (PDSCH) result comprising a cyclic redundancy check (CRC) pass rate of 100%.

25. The apparatus of claim 19, wherein the at least one processor is configured to:
measure an inactive set of antennas in response to at least the channel condition of an active set of antennas is less than a first threshold (T0); and
switch to the inactive set of antennas if the channel condition of the inactive set of antennas is greater than T0 or the active set of antennas.

26. (canceled)

27. (canceled)

28. A method of wireless communication at user equipment (UE), comprising:
measuring a channel condition for a first set of antennas and a second set of antennas at the UE; and
dynamically selecting, while in a radio resource control (RRC) idle mode, at least one antenna from the first set of antennas or the second set of antennas based on the channel condition.

29. (canceled)

30. (canceled)
